(19) United States
(12) Patent Application Publication
(10) Pub. No.: US 2025/0393354 A1
(43) Pub. Date: Dec. 25, 2025

(54) DISPLAY PANEL, DISPLAY DEVICE INCLUDING THE DISPLAY PANEL, AND ELECTRONIC DEVICE INCLUDING THE DISPLAY PANEL

(71) Applicant: Samsung Display Co., LTD., Yongin-si (KR)

(72) Inventor: Jun Hyun PARK, Yongin-si (KR)

(21) Appl. No.: 19/189,615

(22) Filed: Apr. 25, 2025

(30) Foreign Application Priority Data
Jun. 20, 2024 (KR) 10-2024-0080049
Sep. 19, 2024 (KR) 10-2024-0126887

(51) Int. Cl. H10H 29/32; G02B 27/01; H10H 29/39; H10H 29/49; H10K 59/121; H10K 59/123; H10K 59/131

(52) U.S. Cl. CPC H10H 29/32; H10H 29/39; H10H 29/49; H10K 59/1213; H10K 59/1216; H10K 59/123; H10K 59/131; G02B 27/0172

(57) ABSTRACT

There are provided a display panel, a display device including the display panel, and an electronic device including the display panel, in which the degree of integration of pixels is increased. The display panel may include a display area in which a first pixel and a second pixel connected to the first pixel through a connection electrode are disposed. The display panel may include a non-display area at the periphery of the display area.

This application claims priority to Korean Patent Application No. 10-2024-0080049, filed on Jun. 20, 2024, and Korean Patent Application No. 10-2024-0126887 filed on Sep. 19, 2024, and all the benefits accruing therefrom under 35 U.S.C. § 119, the contents of which in their entirety are herein incorporated by reference.

### BACKGROUND

### 1. Field

The present disclosure generally relates to a display panel, a display device including the display panel, and an electronic device including the display panel.

### 2. Related Art

With the development of information technologies, the importance of a display device which is a connection medium between a user and information increases. Accordingly, display devices such as, for example, a liquid crystal display device and an organic light emitting display device are increasingly used. Attempts to provide display devices having high resolution have been conducted. To this end, techniques for increasing the degree of integration of pixels is desired.

### SUMMARY

Embodiments provide a display panel, a display device including the display panel, and an electronic device including the display panel, in which the degree of integration of pixels can be increased.

In accordance with an aspect of the present disclosure, a display panel includes: a display area in which a first pixel and a second pixel connected to the first pixel through a connection electrode are disposed; and a non-display area at a periphery of the display area, wherein the first pixel includes: a first transistor including a gate electrode connected to a first node, the first transistor being connected between a first power line and a second node; a second transistor connected between the first node and a third node; a third transistor connected between the second node and the third node; and a first hold capacitor including an electrode connected to the connection electrode through the third node and another electrode connected to a data line, and wherein the second pixel includes: a fourth transistor including a gate electrode connected to a fourth node, the fourth transistor being connected to the first power line; a fifth transistor connected between the fourth node and a sixth node; and a second hold capacitor including an electrode connected to the connection electrode through the sixth node and another electrode connected to the data line.

The first pixel may further include a first storage capacitor including an electrode connected to the first node and another electrode connected to a third power line. The second pixel may further include a second storage capacitor including an electrode connected to the fourth node and another electrode connected to the third power line.

Each of the first to fifth transistors may include a P-type semiconductor.

A second power line to which a second power voltage is applied may be further disposed in the display area. The first pixel may further include a first light emitting element disposed between the first transistor and the second power line. The second pixel may further include a second light emitting element disposed between the fourth transistor and the second power line.

The first light emitting element and the second light emitting element may be configured to simultaneously emit light.

The second transistor may include a gate electrode connected to an ith first scan line, wherein i is an integer of 1 or more, the third transistor may include a gate electrode connected to ith second scan line, and the fifth transistor may include a gate electrode connected to an (i+1)th first scan line.

A quantity of first scan lines disposed in the display area may be equal to a quantity of second scan lines disposed in the display area.

A quantity of first scan lines disposed in the display area may be at least two times greater than a quantity of second scan lines disposed in the display area.

Each of the ith first scan line, the ith second scan line, and an (i+1)th first scan line may extend in a first direction. The data line may extend in a second direction different from the first direction. The connection electrode may extend in the second direction.

The fourth transistor may be connected between the first power line and a fifth node. The second pixel may further include a sixth transistor connected between the fifth node and the sixth node.

The second transistor may include a gate electrode connected to an ith first scan line, wherein i is an integer of 1 or more, the third transistor may include a gate electrode connected to an ith second scan line, the fifth transistor includes a gate electrode connected to an (i+1)th first scan line, and the sixth transistor may include a gate electrode connected to an (i+1)th second scan line.

The display panel may be configured to integrally initialize respective voltages of the second node and the fifth node.

The display panel may be configured to integrally compensate characteristic value changes of the first transistor and the fourth transistor.

In accordance with an aspect of the present disclosure, a display device includes: a display panel in which a unit pixel, a data line, and a first power line are disposed, wherein the unit pixel includes a first pixel, a second pixel, and a connection electrode connected to the first pixel and the second pixel; and a data driving circuit configured to supply a data voltage to the data line, wherein the first pixel includes: a first transistor including a gate electrode connected to a first node, the first transistor being connected between the first power line and a second node; a second transistor connected between the first node and a third node; a third transistor connected between the second node and the third node; and a first hold capacitor including an electrode connected to the connection electrode through the third node and another electrode connected to the data line, and wherein the second pixel includes: a fourth transistor including a gate electrode connected to a fourth node, the fourth transistor being connected to the first power line; a fifth transistor connected between the fourth node and a sixth node; and a second hold capacitor including an electrode connected to the connection electrode through the sixth node and another electrode connected to the data line.

The display device may further include a power supply circuit configured to supply a first power voltage to the first power line such that the first power voltage alternately has a first voltage of a high level and a second voltage of a low level.

The power supply circuit may be configured to supply the first power voltage such that the first power voltage has the first voltage in a first period, wherein the first period is an on-bias period, supply the first power voltage such that the first power voltage has the second voltage in a second period, wherein the second period is an initialization period, supply the first power voltage such that the first power voltage has the first voltage in a third period, wherein the third period is a compensation period, supply the first power voltage such that the first power voltage has the second voltage in a fourth period and a fifth period, wherein the fourth period is a data writing period and the fifth period is a margin period, and supply the first power voltage such that the first power voltage has the first voltage in a sixth period, wherein the sixth period is an emission period.

A third power line may be further disposed in the display panel. The first pixel may further include a first storage capacitor including an electrode connected to the first node and another electrode connected to the third power line. The second pixel may further include a second storage capacitor including an electrode connected to the fourth node and another electrode connected to the third power line. The power supply circuit may be configured to configured to supply, to the third power line, a third power voltage such that the third power voltage alternately has a fifth voltage of a high level and a sixth voltage of a low level.

The power supply circuit may be configured to supply the third power voltage such that the third power voltage has the sixth voltage in the first period and the second period, supply the third power voltage such that the third power voltage has the fifth voltage in the third period and the fourth period, supply the third power voltage such that the third power voltage has the sixth voltage in the fifth period, and supply the third power voltage such that the third power voltage has the fifth voltage in the sixth period.

A second power line to which a second power voltage is applied may be further disposed in the display panel. The first pixel may further include a first light emitting element disposed between the first transistor and the second power line. The second pixel may further include a second light emitting element disposed between the fourth transistor and the second power line. The power supply circuit may be configured to supply the second power voltage such that the second power voltage has a third voltage of a high level in the first to fourth periods and supply the second power voltage such that the second power voltage has a fourth voltage of a low level in the fifth period and the sixth period.

The display device may further include a scan driving circuit configured to supply a first scan signal to each of a plurality of first scan lines disposed in the display panel, and supply a second scan signal to each of a plurality of second scan lines disposed in the display panel. The second transistor may include a gate electrode connected to an ith first scan line among the plurality of first scan lines, wherein i is an integer of 1 or more. The third transistor may include a gate electrode connected to an ith second scan line among the plurality of second scan lines. The fifth transistor may include a gate electrode connected to an (i+1)th first scan line among the plurality of first scan lines. A sixth transistor included in the second pixel may include a gate electrode connected to an (i+1)th second scan line among the plurality of second scan lines. The scan driving circuit may be configured to: supply the first scan signal such that the first scan signal has an off-level to the ith first scan line in the first period, the fifth period, and the sixth period, supply the first scan signal such that the first scan signal has an on-level to the ith first scan line in the second period, the third period, and the fourth period, supply the second scan signal such that the second scan signal has an off-level to the ith second scan line in the first period, the fourth period, the fifth period, and the sixth period, and supply the second scan signal such that the second scan signal has an on-level to the ith second scan line in the second period and the third period.

In accordance with an aspect of the present disclosure, an electronic device includes: a processor configured to output first image data; and a display device configured to display an image corresponding to the first image data, wherein the display device includes: a display panel in which a unit pixel, a data line, and a first power line are disposed, wherein the unit pixel includes a first pixel, a second pixel, and a connection electrode connected to the first pixel and the second pixel; and a data driving circuit configured to supply a data voltage corresponding to the first image data to the data line, wherein the first pixel includes: a first transistor including a gate electrode connected to a first node, the first transistor being connected between the first power line and a second node; a second transistor connected between the first node and a third node; a third transistor connected between the second node and the third node; and a first hold capacitor including an electrode connected to the connection electrode through the third node and another electrode connected to the data line, and wherein the second pixel includes: a fourth transistor including a gate electrode connected to a fourth node, the fourth transistor being connected to the first power line; a fifth transistor connected between the fourth node and a sixth node; and a second hold capacitor including an electrode connected to the connection electrode through the sixth node and another electrode connected to the data line.

### BRIEF DESCRIPTION OF THE DRAWINGS

Example embodiments will now be described more fully hereinafter with reference to the accompanying drawings; however, aspects supported by the present disclosure may be embodied in different forms and should not be construed as limited to the embodiments set forth herein. Rather, the example embodiments are provided such that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a system block diagram of a display device in accordance with embodiments of the present disclosure.

FIG. 2 is an equivalent circuit diagram of a pixel in accordance with embodiments of the present disclosure.

FIG. 3 is a diagram briefly illustrating at least a portion of a display area in accordance with embodiments of the present disclosure.

FIG. 4 is an equivalent circuit diagram of a unit pixel in accordance with an embodiment of the present disclosure.

FIG. 5 is a diagram briefly illustrating at least a portion of a display area in accordance with embodiments of the present disclosure.

FIG. 6 is a timing diagram illustrating a method of driving the display device in accordance with an embodiment of the present

FIGS. 7 to 12 are diagrams illustrating the method in the unit pixel illustrated in FIG. 4.

FIG. 13 is an equivalent circuit diagram of a unit pixel in accordance with another embodiment of the present disclosure.

FIG. 14 is a diagram briefly illustrating at least a portion of a display area in accordance with another embodiment of the present disclosure.

FIGS. 15 to 20 are diagrams illustrating the method in the unit pixel illustrated in FIG. 13.

FIG. 21 is a diagram illustrating an embodiment of a display system in accordance with embodiments of the present disclosure.

FIG. 22 is a view illustrating an application example of the display system illustrated in FIG. 21.

FIG. 23 is a view illustrating a head mounted display device worn by a user.

### DETAILED DESCRIPTION

Hereinafter, example embodiments are described in detail with reference to the accompanying drawings such that those skilled in the art may easily practice the present disclosure. The present disclosure may be implemented in various different forms and is not limited to the example embodiments described in the present specification.

A part irrelevant to the description will be omitted to clearly describe the present disclosure, and the same or similar constituent elements will be designated by the same reference numerals throughout the specification. Therefore, the same reference numerals may be used in different drawings to identify the same or similar elements.

In some aspects, the size and thickness of each component illustrated in the drawings are arbitrarily illustrated for better understanding and ease of description, but embodiments of the present disclosure are not limited thereto. Thicknesses of several portions and regions are exaggerated for clear expressions.

In description, the expression “equal” may mean “substantially equal.” That is, this may mean equality to a degree to which those skilled in the art can understand the equality. Other expressions may be expressions in which “substantially” is omitted. The term “substantially,” as used herein, may mean approximately or actually.

It will be understood that, although the terms “first”, “second,” and the like may be used herein to describe various elements, these elements should not be limited by these terms. These terms are used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

The terms “under,” “beneath,” “on,” “above,” and the like are used to describe a relationship between components illustrated in a drawing. The terms are relative and are described with reference to a direction indicated in the drawing.

Unless defined otherwise, it is to be understood that all the terms (including technical and scientific terms) used in the specification have the same meaning as those that are understood by those who skilled in the art. Further, the terms defined by the dictionary generally used should not be ideally or excessively formally defined unless clearly defined specifically.

It will be further understood that the terms “comprises”, “comprising”, “includes”, “including”, and the like, when used herein, specify the presence of stated features, integers, steps, operations, elements, and/or components, but do not preclude the presence and/or addition of one or more other features, integers, steps, operations, elements, components, and/or groups thereof.

Hereinafter, example embodiments of the present disclosure will be described in detail with reference to the accompanying drawings.

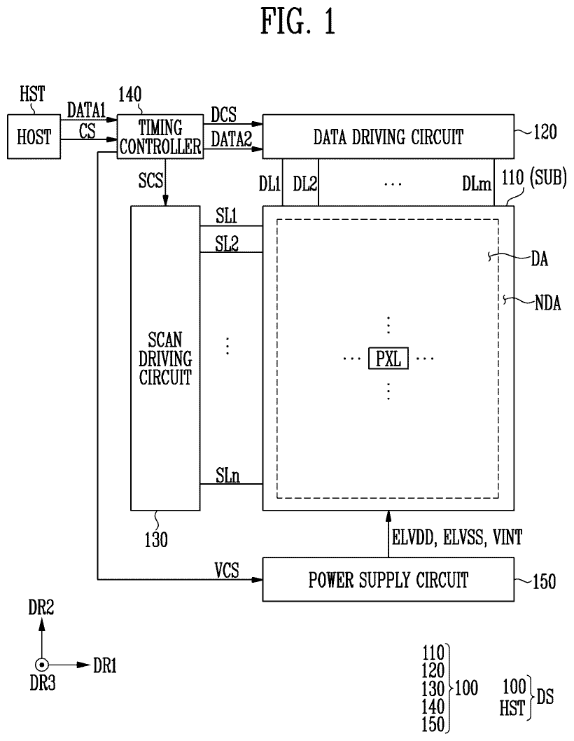

FIG. 1 is a system block diagram of a display device 100 in accordance with embodiments of the present disclosure.

Referring to FIG. 1, the display device 100 in accordance with the embodiments of the present disclosure may include a display panel 110, a data driving circuit 120, a scan driving circuit 130, a power supply circuit 150, a timing controller 140, and the like.

The display panel 110 may include a substrate SUB. The display panel 110 may include, on the substrate SUB, a display area DA in which a plurality of pixels PXL are located and a non-display area NDA at the periphery of the display area DA. A plurality of data lines DL1 to DLm (m is an integer of 2 or more) and a plurality of scan lines SL1 to SLn (n is an integer of 2 or more), which are electrically connected to the plurality of pixels PXL, may be disposed in the display panel 110 (or the display area DA). At least one power line configured to apply a power voltage to the plurality of pixels PXL may be disposed in the display panel 110. The non-display area NDA may be located in a peripheral area of the display area DA (e.g., an edge area of the display area DA). At least one pad may be located in the non-display area NDA, and a data voltage, a power voltage, and the like may be supplied to the plurality of data lines DL1 to DLm through the pad.

The display panel 110 may be formed flat, but embodiments of the present disclosure are not limited thereto. For example, the display panel 110 may include curved portions formed at left and right ends of the display panel 110. A curved surface may have a constant curvature or have a changed curvature. Besides, the display panel 110 may be formed flexible such that the display panel 110 is curvable, warpable, bendable, foldable, and/or rollable.

In an embodiment, the substrate SUB may include a rigid glass substrate. However, embodiments of the present disclosure are not limited thereto, and the substrate SUB may include a plastic substrate having flexibility. In an example, the plastic substrate may be implemented as a polyimide (PI) substrate. In another embodiment, the substrate SUB may be implemented as a silicon substrate.

The plurality of data lines DL1 to DLm may extend in one direction in the display panel 110. The one direction may be, for example, a second direction DR2. The plurality of data lines DL1 to DLm may be disposed in the display panel 110 while extending in the second direction DR2 (e.g., entirely in the second direction DR2). The second direction DR2 may be, for example, a direction crossing from an upper side to a lower side of the display panel 110, but embodiments of the present disclosure are not limited thereto.

The plurality of scan lines SL1 to SLn may extend in one direction in the display panel 110. The one direction may be, for example, a first direction DR1. The plurality of scan lines SL1 to SLn may be disposed in the display panel 110 while extending in the first direction (e.g., entirely in the first direction DR1). The first direction DR1 may be a direction different from the second direction DR2, but embodiments of the present disclosure are not limited thereto. The first direction DR1 may be, for example, a direction crossing from a left side to a right side of the display panel 110.

The data driving circuit 120 may be configured to supply a data voltage to the plurality of data lines DL1 to DLm. The data driving circuit 120 may generate a data voltage, based on second image data DATA2 and a data driving circuit control signal DCS, and output the generated data voltage to the plurality of data lines DL1 to DLm in synchronization with a timing. The data driving circuit control signal DCS may include, for example, a Source Start Pulse (SSP) signal, a Source Shift Clock (SSC) signal, a Source Output Enable (SOE) signal, and the like.

The data driving circuit 120 may be implemented as an integrated circuit (e.g., a Source Driver Integrated Circuit (SDIC) formed separately form the display panel 110. The data driving circuit 120 may be formed together with the display panel 110 in at least a partial area on the non-display area NDA of the display panel 110.

The scan driving circuit 130 may be configured to output a scan signal to the plurality of scan lines SL1 to SLn in response to a scan driving circuit control signal SCS. The scan driving circuit control signal SCS may include a start signal indicating a start of a frame, a horizontal synchronization signal for outputting the scan signal in synchronization with a timing, and the like.

The scan driving circuit 130 may be implemented as an integrated circuit (e.g., a Gate Driver Integrated Circuit (GDIC) formed separately form the display panel 110. The scan driving circuit 130 may be formed together with the display panel 110 in at least a partial area on the non-display area NDA of the display panel 110.

The power supply circuit 150 may be configured to output a constant voltage having a constant voltage level. The power supply circuit 150 may output a power voltage (e.g., a first power voltage ELVDD, a second power voltage ELVSS, a third power voltage VINT, or the like) supplied to the display panel 110. In some embodiments, the power supply circuit 150 may output a voltage (e.g., a gate high voltage, a gate low voltage, or the like) supplied to the scan driving circuit 130. In some embodiments, the power supply circuit 150 may output a voltage (e.g., a gamma voltage or the like) supplied to the data driving circuit 120. The power supply circuit 150 may include, for example, a regulator (e.g., a Low Dropout (LDO) regulator, or the like). The power supply circuit 150 may be implemented as, for example, a Power Management Integrated Circuit (PMIC). The power supply circuit 150 may be configured to output a power voltage to power lines in response to a power supply circuit control signal VCS.

The timing controller 140 may be configured to control the data driving circuit 120, the scan driving circuit 130, the power supply circuit 150, and the like. The timing controller 140 may generate and output the control signals DCS, SCS, and VCS for controlling the data driving circuit 120, the scan driving circuit 130, and the power supply circuit 150, based on a control signal CS (e.g., a synchronization signal, a clock signal, a data enable signal, or the like) input through a host HST. In some embodiments, the timing controller 140 may generate the synchronization signal, the data enable signal, and the like therein, based on the control signal CS input through the host HST (e.g., information on a driving frequency (or frame rate) of an image displayed on the display panel 110).

The timing controller 140 may receive first image data DATA1 input from the host HST, and align the input first image data DATA1 in a pixel row unit. The timing controller 140 may convert the input first image data DATA1 in synchronization with a predetermined interface (e.g., a Low Voltage Differential Signaling (LVDS), a Display Port (DP), an embedded Display Port (eDP), or the like). The second image data DATA2 which the timing controller 140 outputs to the data driving circuit 120 may be one converted inside the timing controller 140 according to the predetermined interface.

In some embodiments, the timing controller 140 may be disposed in a logic type in the display device 100. In some embodiments, the timing controller 140 may be disposed in a processor type in the display device 100. The timing controller 140 may include at least one memory (e.g., a register or the like).

The host HST may include a set-top box, an Application Processor (AP), and the like. In an embodiment, the host HST may be a component at the outside of the display device 100, which is not included in the display device 100. In an embodiment, the host HST may be mounted in the display device 100. The first image data DATA1 and the control signal CS may be transmitted/received between the host HST and the display device 100 through an interface. The interface may be, for example, a Serial Programming Interface (SPI), an Inter Integrated Circuit (12C), a Mobile Industry Processor Interface (MIPI), or the like. However, embodiments of the present disclosure are not limited thereto.

An electronic device DS in accordance with embodiments of the present disclosure may include the display device 100 and the host HST.

In FIG. 1, circuits supplying signals, voltages, and the like to the display panel 110 are classified according to functions. For example, the data driving circuit 120 and the timing controller 140 may be formed in one integrated circuit. The data driving circuit 120 and the timing controller 140 may be ones classified in one integrated circuit according to functions in the display device 100.

The display device 100 in accordance with the embodiments of the present disclosure may be used as a display screen of not only portable electronic devices such as, for example, a mobile phone, a smart phone, a tablet personal computer (PC), a mobile communication terminal, an electronic notebook, an electronic book, a portable multimedia player (PMP), a navigation system, and an ultra-mobile PC (UMPC), but also various products such as, for example, a television, a notebook computer, a monitor, an advertisement board, and an Internet of Things (IOT) device.

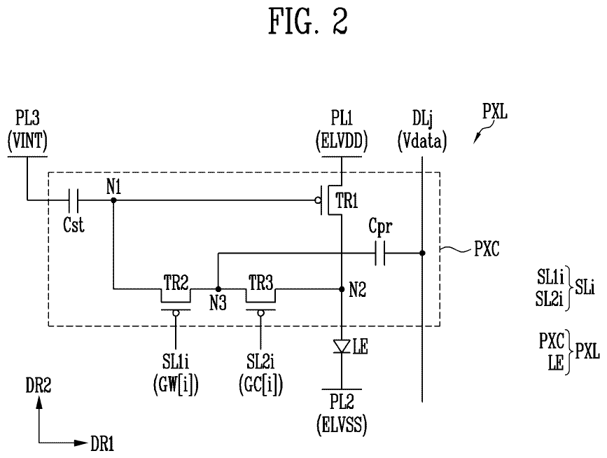

FIG. 2 is an equivalent circuit diagram of a pixel PXL in accordance with embodiments of the present disclosure.

Referring to FIG. 2, the pixel PXL in accordance with the embodiments of the present disclosure may include a pixel circuit PXC and a light emitting element LE.

The pixel circuit PXC may include at least two switching elements and at least one storage element. In an embodiment, the switching element may include a transistor. In an embodiment, the storage device may include a capacitor. Referring to FIG. 2, an embodiment in which the pixel PXL in accordance with the embodiments of the present disclosure includes three transistors and two capacitors is illustrated. However, embodiments of the present disclosure are not limited thereto, and the pixel circuit PXC may be freely selected according to selection of those skilled in the art. Hereinafter, an embodiment in which the pixel circuit PXC includes three transistors and two capacitors will be described as an example.

Referring to FIG. 2, the pixel circuit PXC in accordance with the embodiments of the present disclosure may include first to third transistors TR1 to TR3 and first and second capacitors Cst and Cpr.

The first transistor TR1 may include a gate electrode connected to a first node N1, a first electrode connected to a first power line PL1, and a second electrode connected to a second node N2. The first electrode may be any one (e.g., a source electrode) of the source electrode and a drain electrode. The second electrode may be the other (e.g., the drain electrode) of the source electrode and the drain electrode. The first power voltage ELVDD may be applied to the first power line PL1. The first transistor TR1 may be configured to provide a current (e.g., a driving current) corresponding to a voltage level applied to the first node N1. The first transistor TR1 may be referred to as a driving transistor.

The second transistor TR2 may be configured to switch an electrical connection between the first node N1 and a third node N3 in response to a first scan signal GW[i] (i is an integer of 1 or more). The second transistor TR2 may include a gate electrode connected to an ith first scan line SL1i. The first scan signal GW[i] may be applied to the ith first scan line SL1i. The second transistor TR2 may electrically connect between the first node N1 and the third node N3 in response to the first scan signal GW[i] having a turn-on level.

The third transistor TR3 may be configured to switch an electrical connection between the second node N2 and the third node N3 in response to a second scan signal GC[i]. The third transistor TR3 may include a gate electrode connected to an ith second scan line SL2i. The second scan signal GC[i] may be applied to the ith second scan line SL2i. The third transistor TR3 may electrically connect between the second node N2 and the third node N3 in response to the second scan signal GC[i] having a turn-on level.

The first capacitor Cst may include an electrode connected to the first node N1 and another electrode connected to a third power line PL3. The third power voltage VINT may be applied to the third power line PL3. The electrode and the other electrode may be located while facing each other by a predetermined area (e.g., while facing each other by the predetermined area in a vertical direction). The first capacitor Cst may be configured to maintain a potential difference between the third power line PL3 and the first node N1. The first capacitor Cst may be referred to as a storage capacitor Cst.

The second capacitor Cpr may include an electrode connected to the third node N3 and another electrode connected to a jth (j is an integer of 1 or more) data line DLj. A data voltage Vdata may be applied to the jth data line DLj. The electrode and the other electrode may be located while facing each other by a predetermined area (e.g., while facing each other by the predetermined area in the vertical direction). The second capacitor Cpr may be configured to maintain a potential difference between the jth data line DLj and the third node N3. The second capacitor Cpr may be referred to as a hold capacitor Cpr.

The light emitting element LE may be connected between the second node N2 and a second power line PL2. The second power voltage ELVSS may be applied to the second power line PL2. The light emitting element LE may include a first electrode (e.g., an anode electrode) connected to the second node N2 and a second electrode (e.g., a cathode electrode) connected to the second power line PL2. A light emitting layer may be located between the first electrode and the second electrode. In some embodiments, the light emitting layer may be implemented as an organic light emitting layer including an organic light emitting material. However, embodiments of the present disclosure are not limited thereto, and the light emitting layer may include an inorganic light emitting material, a quantum dot, a nano rod, or the like.

Referring to FIG. 2, the first to third transistors TR1 to TR3 may all be implemented with a transistor including a P-type semiconductor. Accordingly, the first to third transistors TR1 to TR3 may turn on in response to a low level voltage, and the first to third transistors TR1 to TR3 may turn off in response to a high level voltage. However, embodiments of the present disclosure are not limited thereto, and at least one of the first to third transistors TR1 to TR3 may be implemented with a transistor including an N-type semiconductor. The transistor including the N-type transistor may turn on in response to the high level voltage, and the transistor including the N-type transistor may turn off in response to the low level voltage. Hereinafter, for convenience of descriptions, an embodiment in which the first to third transistors TR1 to TR3 are all implemented with a transistor including a P-type semiconductor will be described as an example. However, embodiments of the present disclosure are not limited thereto.

In an embodiment, each of the first to third transistors TR1 to TR3 may be implemented with a polycrystalline silicon transistor. For example, each of the first to third transistors TR1 to TR3 may include a semiconductor formed through a Low Temperature Polycrystalline Silicon (LTPS) process. However, embodiments of the present disclosure are not limited thereto. For example, at least one of the first to third transistors TR1 to TR3 may include an oxide semiconductor.

Referring to FIG. 2, an ith scan line may include the ith first scan line SL1i and the ith second scan line SL2i.

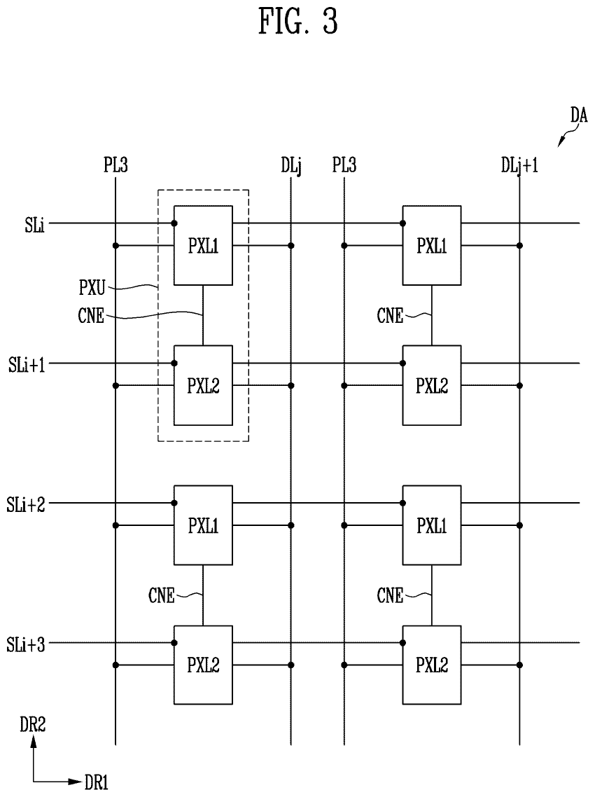

FIG. 3 is a diagram briefly illustrating at least a portion of a display area DA in accordance with embodiments of the present disclosure.

For convenience of description, some components disposed in the display area DA are not illustrated. For example, the first power line PL1 and the second power line PL2, which are described with reference to FIG. 2, may be disposed in the display area DA, but are not illustrated for convenience of description.

Referring to FIG. 3, a unit pixel PXU may be disposed in the display area DA in accordance with the embodiments of the present disclosure. The unit pixel PXU may include a connection electrode CNE. Pixels disposed in the unit pixel PXU may be connected to each other through the connection electrode CNE. The connection electrode CNE may extend in the second direction DR2.

In an embodiment, the unit pixel PXU may include a first pixel PXL1 and a second pixel PXL2, which are located adjacent to each other in the second direction DR2. However, embodiments of the present disclosure are not limited thereto, and the unit pixel PXU may include three or more pixels disposed side by side in the second direction DR2. Hereinafter, an embodiment in which the unit pixel PXU includes two pixels adjacent to each other will be described as an example. However, embodiments of the present disclosure are not limited thereto.

The term “adjacent” herein may refer to elements which are relatively close to each other (e.g., within a target distance). In some other cases, the term “adjacent” herein may refer to elements which are in contact with each other. In some cases, the term “adjacent” herein may refer to elements of the same type, in which another element of the same type is not disposed between the elements. For example, for the first pixel PXL1 and the second pixel PXL2 described as adjacent to each other, another pixel is not present between the first pixel PXL1 and the second pixel PXL2.

Referring to FIG. 3, four unit pixels PXU disposed in two rows and two columns. These unit pixels may be referred to as a unit pixel located at a left upper end, a unit pixel located at a right upper end, a unit pixel located at a left lower end, and a unit pixel located at a right lower end.

A first pixel PXL1 of the unit pixel located at the left upper end may be connected to the third power line PL3, an ith scan line SLi, a jth data line DLj, a connection electrode CNE, and the like.

A second pixel PXL2 of the unit pixel located at the left upper end may be connected to the third power line PL3, an (i+1)th scan line SLi+1, the jth data line DLj, the connection electrode CNE, and the like.

A first pixel PXL1 of the unit pixel located at the right upper end may be connected to the third power line PL3, the ith scan line SLi, a (j+1)th data line DLj+1, a connection electrode CNE, and the like.

A second pixel PXL2 of the unit pixel located at the right upper end may be connected to the third power line PL3, the (i+1)th scan line SLi+1, the (j+1)th data line DLj+1, the connection electrode CNE, and the like.

A first pixel PXL1 of the unit pixel located at the left lower end may be connected to the third power line PL3, an (i+2)th scan line SLi+2, the jth data line DLj, a connection electrode CNE, and the like.

A second pixel PXL2 of the unit pixel located at the left lower end may be connected to the third power line PL3, an (i+3)th scan line SLi+3, the jth data line DLj, the connection electrode CNE, and the like.

A first pixel PXL1 of the unit pixel located at the right lower end may be connected to the third power line PL3, the (i+2)th scan line SLi+2,, the (j+1)th data line DLj+1, a connection electrode CNE, and the like.

A second pixel PXL2 of the unit pixel located at the right lower end may be connected to the third power line PL3, the (i+3)th scan line SLi+3, the (j+1)th data line DLj+1, the connection electrode CNE, and the like.

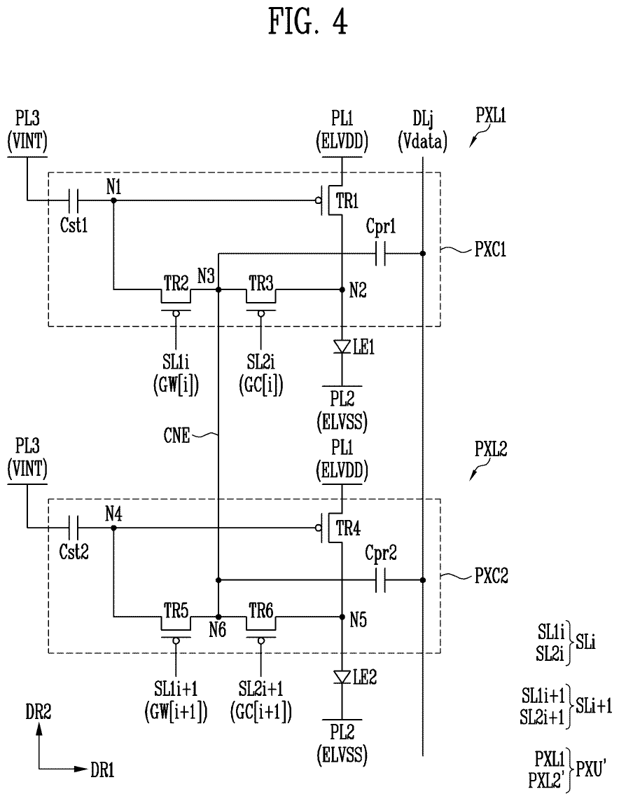

FIG. 4 is an equivalent circuit diagram of a unit pixel PXU in accordance with an embodiment of the present disclosure.

Referring to FIG. 4, the unit pixel PXU may include a first pixel PXL1 and a second pixel PXL2.

The first pixel PXL1 may include first to third transistors TR1 to TR3, a first storage capacitor Cst1, a first hold capacitor Cpr1, and a first light emitting element LE1. The first to third transistors TR1 to TR3, the first storage capacitor Cst1, the first hold capacitor Cpr1, and the first light emitting element LE1 may respectively correspond to the first to third transistors TR1 to TR3, the first capacitor Cst, the second capacitor Cpr, and the light emitting element LE, which are described with reference to FIG. 2. Each of first to third nodes N1 to N3 of the first pixel PXL1 may respectively correspond to the first to third nodes N1 to N3 described with reference to FIG. 2.

The second pixel PXL2 may include fourth to sixth transistors TR4 to TR6, a second storage capacitor Cst2, a second hold capacitor Cpr2, and a second light emitting element LE2. The fourth to sixth transistors TR4 to TR6, the second storage capacitor Cst2, the second hold capacitor Cpr2, and the second light emitting element LE2 may respectively correspond to the first to third transistors TR1 to TR3, the first capacitor Cst, the second capacitor Cpr, and the light emitting element LE, which are described with reference to FIG. 2. Each of fourth to sixth nodes N4 to N6 of the second pixel PXL2 may respectively correspond to the first to third nodes N1 to N3 described with reference to FIG. 2.

A gate electrode of the fifth transistor TR5 may be connected to an (i+1)th first scan line SL1i+1. A gate electrode of the sixth transistor TR6 may be connected to an (i+1)th second scan line SL2i+1. An (i+1)th scan line SLi+1 may include the (i+1)th first scan line SL1i+1 and the (i+1)th second scan line SL2i+1.

A connection electrode CNE may connect between the third node N3 and the sixth node N6. The connection electrode CNE may be connected to the first hold capacitor Cpr1, the second transistor TR2, the third transistor TR3, the second hold capacitor Cpr2, the fifth transistor TR5, and the sixth transistor TR6.

In accordance with the embodiment of the present disclosure, the first pixel PXL1 and the second pixel PXL2 can be integrally compensated by the connection electrode CNE.

In accordance with the embodiment of the present disclosure, the storage capacity of the first and second hold capacitors Cpr1 and Cpr2 can be increased.

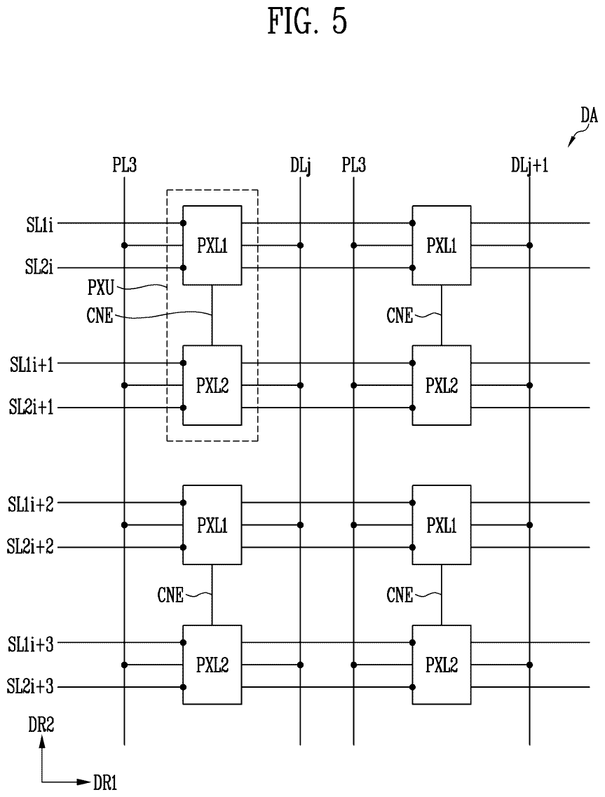

FIG. 5 is a diagram briefly illustrating at least a portion of a display area DA in accordance with embodiments of the present disclosure.

A first pixel PXL1 of a unit pixel located at a left upper end may be connected to the third power line PL3, an ith first scan line SL1i, an ith second scan line SL2i, a jth data line DLj, a connection electrode CNE, and the like.

A second pixel PXL2 of the unit pixel located at the left upper end may be connected to the third power line PL3, an (i+1)th first scan line SL1i+1, an (i+1)th second scan line SL2i+1, the jth data line DLj, the connection electrode CNE, and the like.

A first pixel PXL1 of a unit pixel located at a right upper end may be connected to the third power line PL3, the ith first scan line SL1i, the ith second scan line SL2i, a (j+1)th data line DLj+1, a connection electrode CNE, and the like.

A second pixel PXL2 of the unit pixel located at the right upper end may be connected to the third power line PL3, the (i+1)th first scan line SL1+1, the (i+1)th second scan line SL2i+1, the (j+1)th data line DLj+1, the connection electrode CNE, and the like.

A first pixel PXL1 of a unit pixel located at a left lower end may be connected to the third power line PL3, an (i+2)th first scan line SL1i+2, an (i+2)th second scan line SL2i+2, the jth data line DLj, a connection electrode CNE, and the like.

A second pixel PXL2 of the unit pixel located at the left lower end may be connected to the third power line PL3, an (i+3)th first scan line SL1i+3, an (i+3)th second scan line SL2i+3, the jth data line DLj, the connection electrode CNE, and the like.

A first pixel PXL1 of a unit pixel located at a right lower end may be connected to the third power line PL3, the (i+2)th first scan line SL1i+2, the (i+2)th second scan line SL2i+2, the (j+1)th data line DLj+1, a connection electrode CNE, and the like.

A second pixel PXL2 of the unit pixel located at the right lower end may be connected to the third power line PL3, the (i+3)th first scan line SL1i+3, the (i+3)th second scan line SL2i_3, the (j+1)th data line DLj+1, the connection electrode CNE, and the like.

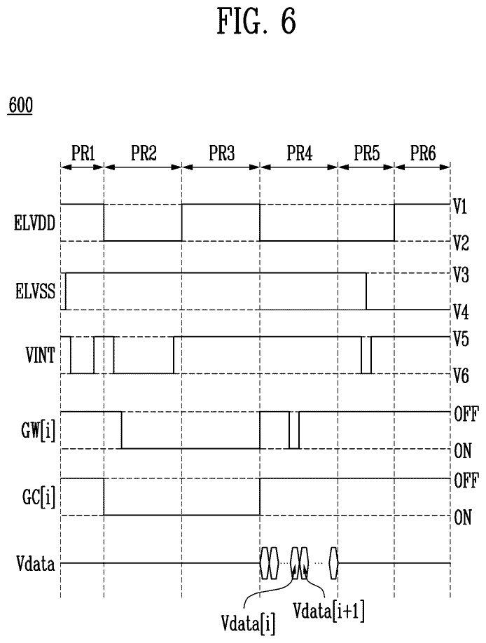

FIG. 6 is a timing diagram illustrating a method 600 of driving the display device in accordance with an embodiment of the present disclosure.

Referring to FIG. 6, the method 600 may include first to sixth periods PR1 to PR6.

In the first period PR1, the first power voltage ELVDD may have a first voltage V1. The second power voltage ELVSS may have a third voltage V3. The third power voltage VINT may have a fifth voltage V5 or a sixth voltage V6. The first scan signal GW[i] may have an off-level OFF. The second scan signal GC[i] may have the off-level OFF. The data voltage Vdata may be in a state in which a predetermined constant voltage is applied or a high impedance state.

Expressions herein of a signal “having” a level (e.g., an off-level OFF, an on-level ON, a high level, a low level, or the like) may refer to a state in which the signal is equal to or set to the described level.

The first voltage V1 may be a voltage of a high level. The third voltage V3 may be a voltage of a high level. The fifth voltage V5 may be a voltage of a high level. The sixth voltage V6 may be a voltage of a low level. The off-level OFF may be a voltage of a high level.

The first period PR1 may be referred as an on-bias period.

In the second period PR2, the first power voltage ELVDD may have a second voltage V2. The second power voltage ELVSS may have the third voltage V3. The third power voltage VINT may have the fifth voltage V5 or the sixth voltage V6. The first scan signal GW[i] may be changed from the off-level OFF to an on-level ON. The second scan signal GC[i] may have the on-level ON. The data voltage Vdata may be in the state in which the predetermined constant voltage is applied or the high impedance state.

The second voltage V2 may be a voltage of a low level. The third voltage V3 may be a voltage of a high level. The fifth voltage V5 may be a voltage of a high level. The sixth voltage V6 may be a voltage of a low level. The off-level OFF may be a voltage of a high level. The on-level ON may be a voltage of a low level.

The second period PR2 may be referred to as an initialization period.

The term “off-level” may be referred to as “turn-off level.” The term “on-level” may be referred to as “turn-on level.” The terms “high level” (or alternatively, “high voltage level”) and “low level” (or alternatively, “low voltage level”) are relative terms describing levels of voltages which, when applied to a transistor described herein, may activate a transistor (e.g., turn “ON” the transistor) or deactivate a transistor (e.g., turn “OFF” the transistor) based on transistor type (e.g., P-type, N-type, or the like) or circuit configuration including the transistor.

In the third period PR3, the first power voltage ELVDD may have the first voltage V1. The second power voltage ELVSS may have the third voltage V3. The third power voltage VINT may have the fifth voltage V5. The first scan signal GW[i] may have the on-level ON. The second scan signal GC[i] may have the on-level ON. The data voltage Vdata may be in the state in which the predetermined constant voltage is applied or the high impedance state.

The first voltage V1 may be a voltage of a high level. The third voltage V may be a voltage of a high level. The fifth voltage V5 may be a voltage of a high level. The on-level ON may be a voltage of a low level.

The third period PR3 may be referred to as a compensation period.

In the fourth period PR4, the first power voltage ELVDD may have the second voltage V2. The second power voltage ELVSS may have the third voltage V3. The third power voltage VINT may have the fifth voltage V5. The first scan signal GW[i] may have the on-level ON. The second scan signal GC[i] may have the off-level OFF. In the data voltage Vdata, a signal may be applied (e.g., by the data driving circuit 120) to each of a plurality of pixel rows.

The second voltage V2 may be a voltage of a low level. The third voltage V3 may be a voltage of a high level. The fifth voltage V5 may be a voltage of a high level. The off-level OFF may be a voltage of a high level. The on-level ON may be a voltage of a low level.

In the data voltage Vdata, a signal written in an ith pixel row may be referred to as “Vdata[i]”. A signal written in an (i+1)the pixel row may be referred to “Vdata[i+1]”.

The fourth period PR4 may be referred to as a data writing period. In the fifth period PR5, the first power voltage ELVDD may

have the second voltage V2. The second power voltage ELVSS may be decreased from the third voltage V3 to a fourth voltage V4. The third power voltage VINT may have the fifth voltage V5 or the sixth voltage V6. The first scan signal GW[i] may have the off-level OFF. The second scan signal GC[i] may have the off-level OFF. The data voltage Vdata may be in the state in which the predetermined constant voltage is applied or the high impedance state.

The second voltage V2 may be a voltage of a low level. The third voltage V3 may be a voltage of a high level. The fourth voltage V4 may be a voltage of a low level. The fifth voltage V5 may be a voltage of a high level. The sixth voltage V6 may be a voltage of a low level. The off-level OFF may be a voltage of a high level.

The fifth period PR5 may be referred to as a margin period.

In the sixth period PR6, the first power voltage ELVDD may have the first voltage V1. The second power voltage ELVSS may have the fourth voltage V4. The third power voltage VINT may have the fifth voltage V5. The first scan signal GW[i] may have the off-level OFF. The second scan signal GC[i] may have the off-level OFF. The data voltage Vdata may be in the state in which the predetermined constant voltage is applied or the high impedance state.

The first voltage V1 may be a voltage of a high level. The fourth voltage V4 may be a voltage of a low level. The fifth voltage V5 may be a voltage of a high level. The off-level OFF may be a voltage of a high level.

The sixth period PR6 may be referred to as an emission period.

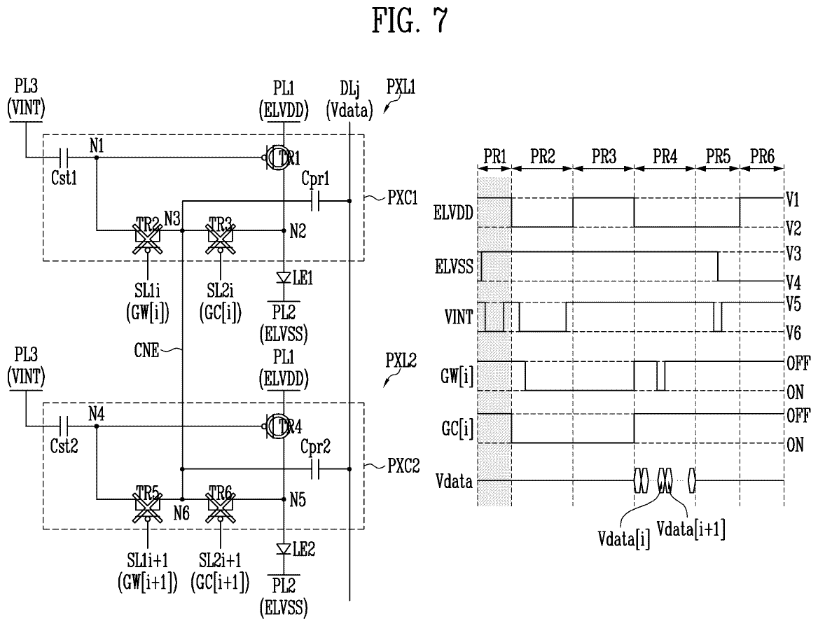

FIGS. 7 to 12 are diagrams illustrating the method 600 (see FIG. 6) in the unit pixel PXU illustrated in FIG. 4.

Referring to FIG. 7, the first pixel PXL1 and the second pixel PXL2 in the first period PR1 are illustrated.

In the first period PR1, the second transistor TR2 and the fifth transistor TR5 may be off. First scan signals GW[i] and GW[i+1] may have the off-level OFF.

In the first period PR1, the third transistor TR3 and the sixth transistor TR6 may be off. Second scan signals GC[i] and GC[i+1] may have the off-level OFF.

The first power voltage ELVDD may have the first voltage V1. The second power voltage ELVSS may have the third voltage V3. The third power voltage VINT may be decreased from the fifth voltage V5 to the sixth voltage V6 and then again increased to the fifth voltage V5. Accordingly, a voltage of each of the first node N1 and the fourth node N4 may also be decreased and then again increased. Accordingly, an on-bias voltage having a turn-on level may be applied to the first and fourth transistors TR1 and TR4, and no driving current may flow through the first and second light emitting elements LE1 and LE2 as the second power voltage ELVSS has the third voltage V3 which has a high level.

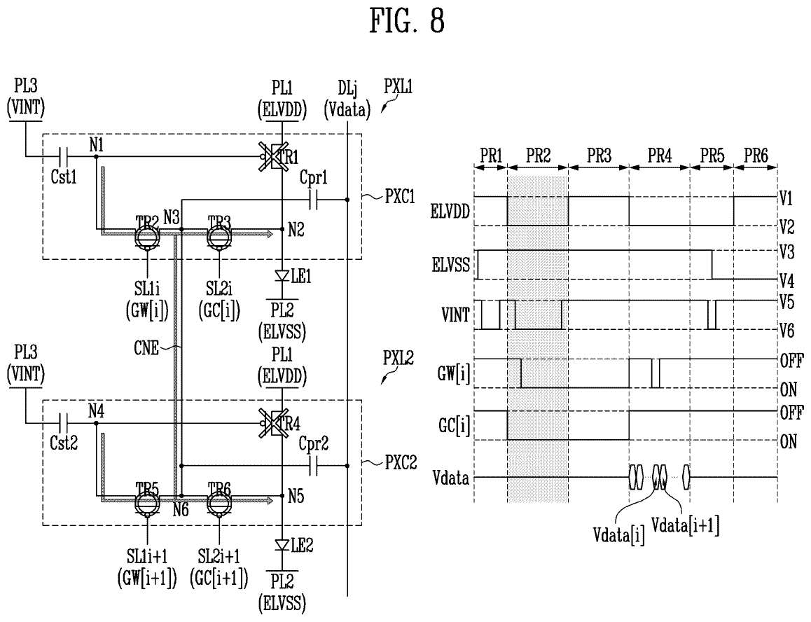

Referring to FIG. 8, the first pixel PXL1 and the second pixel PXL2 in the second period PR2 are illustrated.

In the second period PR2, the second transistor TR2 and the fifth transistor TR5 may be on. The first scan signals GW[i] and GW[i+1] may have the on-level ON.

In the second period PR2, the third transistor TR3 and the sixth transistor TR6 may be on. The second scan signals GC[i] and GC[i+1] may have the on-level ON.

The first node N1, the second node N2, and the third node N3 may be electrically connected to each other. In an example, in response to a voltage level (i.e., third power voltage VINT) of the third power line PL3 being changed from the fifth voltage V5 to the sixth voltage V6, a voltage of each of the first to third nodes N1 to N3 may also be changed and initialized.

The fourth node N4, a fifth node N5, and the sixth node N6 may be electrically connected. In an example, in response to the voltage level of the third power line PL3 being changed from the fifth voltage V5 to the sixth voltage V6, a voltage of each of the fourth to sixth nodes N4 to N6 may also be changed and initialized.

In some embodiments, since the third node N3 and the sixth node N6 are electrically connected to each other by the connection electrode CNE, voltage levels of the second node N2 and the fifth node N5 may be initialized to become equal to each other. For example, embodiments of the present disclosure support controlling respective voltage levels of the second node N2 and the fifth node N5 such that the voltage levels are equal to each other. That is, for example, the display panel 110 may integrally initialize respective voltages of the second node N2 and the fifth node N5.

The first power voltage ELVDD may have the second voltage V2. The second power voltage ELVSS may have the third voltage V3. Accordingly, no driving current may flow toward the first light emitting element LE1 through the first transistor TR1. No driving current may flow toward the second light emitting element LE2 through the fourth transistor TR4.

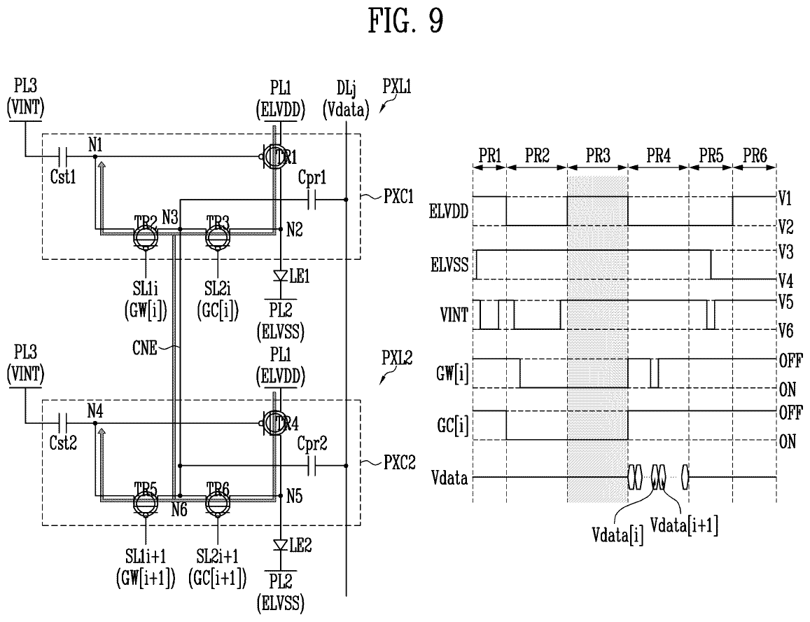

Referring to FIG. 9, the first pixel PXL1 and the second pixel PXL2 in the third period PR3 are illustrated.

In the third period PR3, the second transistor TR2 and the fifth transistor TR5 may be on. The first scan signals GW[i] and GW[i+1] may have the on-level ON.

In the third period PR3, the third transistor TR3 and the sixth transistor TR6 may be on. The second scan signals GC[i] and GC[i+1] may have the on-level ON.

The first power voltage ELVDD may have the first voltage V1. Accordingly, the first transistor TR1 may be diode-connected. Thus, for example, a characteristic value change of the first transistor TR1 (e.g., a change in threshold voltage of the first transistor T1) can be compensated. Similarly, the fourth transistor TR4 may be diode-connected. Thus, for example, a characteristic value change of the fourth transistor TR4 (e.g., a change in threshold voltage of the fourth transistor T4) can be compensated.

In some embodiments, since the third node N3 and the sixth node N6 are electrically connected to each other, the characteristic value changes of the first transistor TR1 and the fourth transistor TR4 can be integrally compensated. That is, for example, the display panel 110 may integrally compensate respective characteristic value changes of the first transistor TR1 and the fourth transistor TR4.

The second power voltage ELVSS may have the third voltage V3. Accordingly, no driving current may flow toward the first light emitting element LE1 from the first transistor TR1. No driving current may flow toward the second light emitting element LE2 from the fourth transistor TR4.

The third power voltage VINT may have the fifth voltage V5. The substantially same potential difference may be formed at both ends of the first storage capacitor Cst1 and the second storage capacitor Cst2.

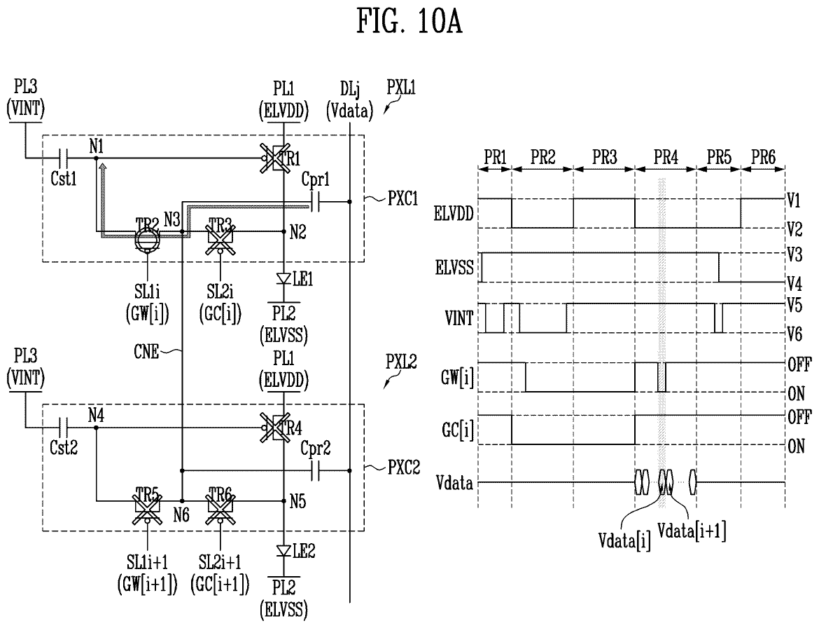

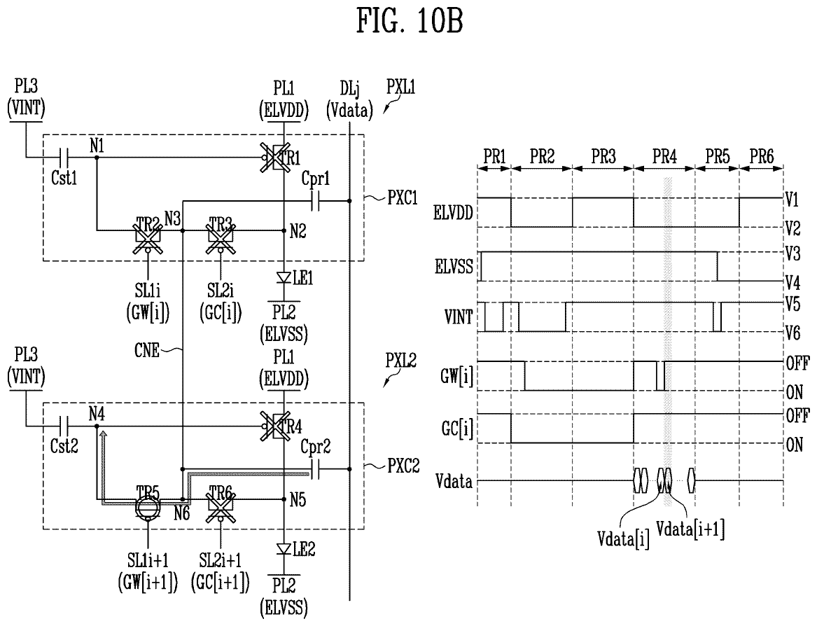

Referring to FIG. 10A, the first pixel PXL1 and the second pixel PXL2 in at least a partial period of the fourth period PR4 are illustrated.

Referring to FIG. 10A, in the at least a partial period of the fourth period PR4, a data voltage Vdata[i] input to the first pixel PXL1 may be applied to the jth data line DLj.

The second transistor TR2 may be turned on based on a voltage level of the first scan signal GW[i]. The first scan signal GW[i] having a turn-on level may be applied to the ith first scan line SL1i. By a coupling effect of the first hold capacitor Cpr1, the voltage of the third node N3 may be changed to have a magnitude corresponding to the data voltage Vdata[i]. The first node N1 and the third node N3 may be electrically connected to each other, and a voltage corresponding to the data voltage Vdata[i] may be applied to the first node N1.

The first transistor TR1 and the third transistor TR3 may be off. The fourth to sixth transistors TR4 to TR6 may be off.

Referring to FIG. 10B, the first pixel PXL1 and the second pixel PXL2 in the other period of the fourth period PR4 are illustrated.

Referring to FIG. 10B, in the other period of the fourth period PR4, a data voltage Vdata[i+1] input to the second pixel PXL2 may be applied to the jth data line DLj.

The fifth transistor TR5 may be turned on based on a voltage level of the first scan signal GW[i+1]. The first scan signal GW[i+1] may be applied to the (i+1)th first scan line SL1i+1. By a coupling effect of the second hold capacitor Cpr2, the voltage of the sixth node N6 may be changed to have a magnitude corresponding to the data voltage Vdata[i+1]. The fourth node N4 may be electrically connected to the sixth node N6, and a voltage corresponding to the data voltage Vdata[i+1] may be applied to the fourth node N4.

The fourth transistor TR4 and the sixth transistor TR6 may be off. The first to third transistors TR1 o TR3 may be off.

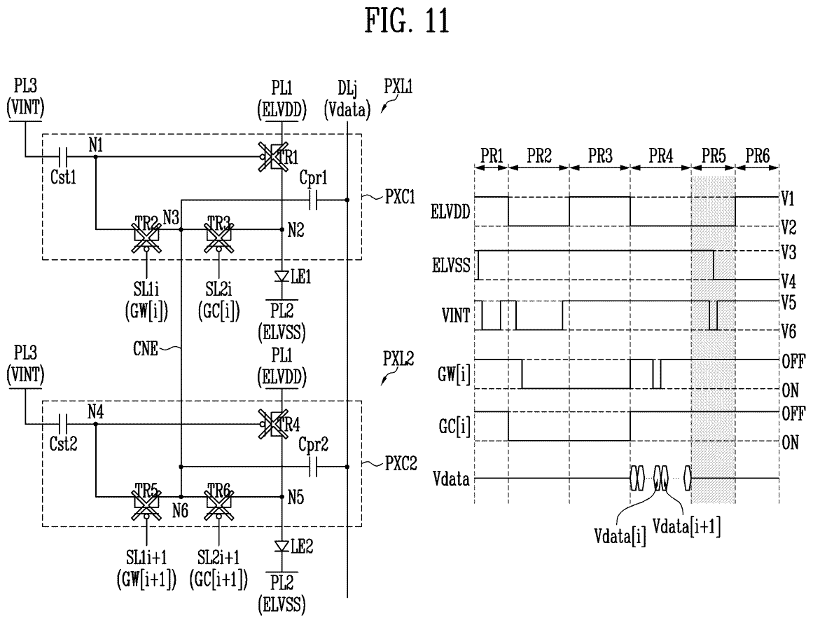

Referring to FIG. 11, the first pixel PXL1 and the second pixel PXL2 in the fifth period PR5 are illustrated.

The first power voltage ELVDD may have the second voltage V2. The second power voltage ELVSS may be decreased from the third voltage V3 to the fourth voltage V4.

The third power voltage VINT may be decreased from the fifth voltage V5 to the sixth volage V6 and then again increased to the fifth voltage V5 before/after a time point at which the second power voltage ELVSS is decreased from the third voltage V3 to the fourth voltage V4.

The first to sixth transistors TR1 to TR6 may all be off.

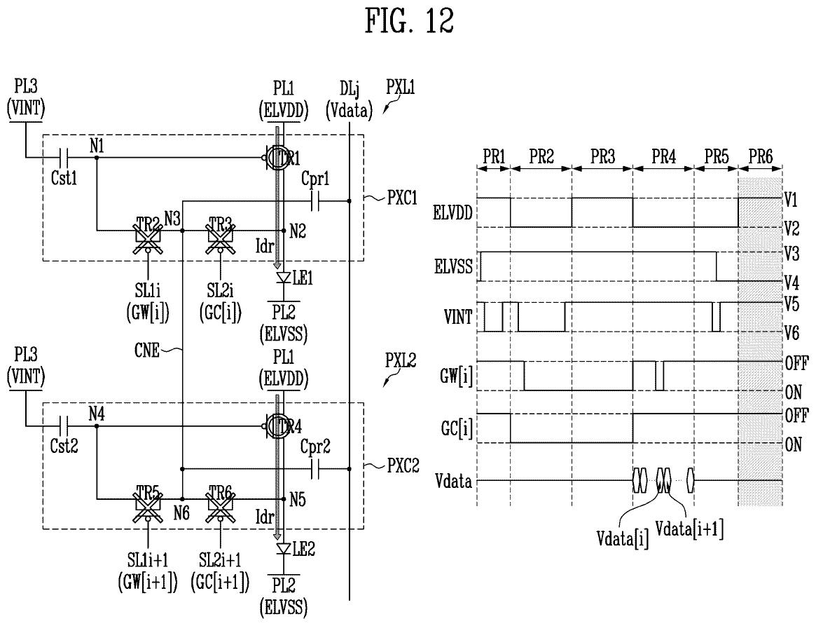

Referring to FIG. 12, the first pixel PXL1 and the second pixel PXL2 in the sixth period PR6 are illustrated.

The first power voltage ELVDD may have the first voltage V1. The second power voltage ELVSS may have the fourth voltage V4. Accordingly, the first transistor TR1 may provide a driving current Idr having a magnitude corresponding to the voltage of the first node N1. The fourth transistor TR4 may provide the driving current Idr having a magnitude corresponding to the voltage of the fourth node N4.

The second transistor TR2, the third transistor TR3, the fifth transistor TR5, and the sixth transistor TR6 may be off.

The first pixel PXL1 and the second pixel PXL2 may emit light simultaneously (or during the same period).

In accordance with the embodiments of the present disclosure, the characteristic value changes of the first transistor TR1 and the fourth transistor TR4 can be integrally compensated.

In some aspects, an effect can be exhibited like that electrodes of the first hold capacitor Cpr1 and the second hold capacitor Cpr2 are electrically connected to each other.

Accordingly, display quality can be improved. Further, the degree of integration of pixels can be improved, thereby increasing Pixel Per Inch (PPI).

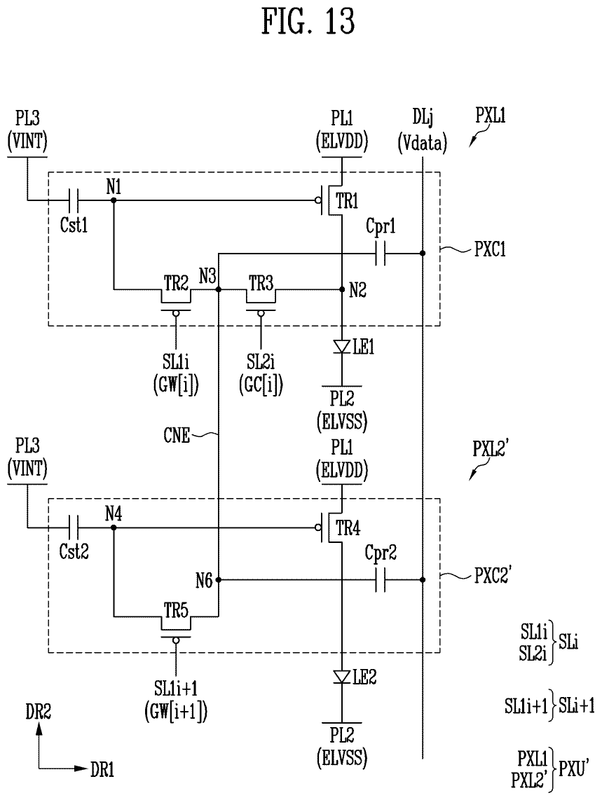

FIG. 13 is an equivalent circuit diagram of a unit pixel PXU′ in accordance with another embodiment of the present disclosure.

Referring to FIG. 13, the unit pixel PXU′ may include a first pixel PXL1 and a second pixel PXL2′.

A first pixel circuit PXC1 of the first pixel PXL may include first to third transistors TR1 to TR3, a first storage capacitor Cst, a first hold capacitor Cpr1, and a first light emitting element LE1. The first to third transistors TR1 to TR3, the first storage capacitor Cst, the first hold capacitor Cpr1, and the first light emitting element LE1 may respectively correspond to the first to third transistors TR1 to TR3, the first capacitor Cst, the second capacitor Cpr, and the light emitting element LE, which are described with reference to FIG. 2. First to third nodes N1 to N3 of the first pixel PXL1 may respectively correspond to the first to third nodes N1 to N3 described with reference to FIG. 2.

A second pixel circuit PXC2′ of the second pixel PXL2′ may include fourth and fifth transistors TR4 and TR5, a second storage capacitor Cst2, a second hold capacitor Cpr2, and a second light emitting element LE2.

As compared with the second pixel PXL2 illustrated in FIG. 4, in the second pixel PXL2′ illustrated in FIG. 13, the sixth transistor TR6 may be omitted. Accordingly, the (i+1)th second scan line SL2i+1 may be omitted.

A connection electrode CNE may connect between the third node N3 and a sixth node N6. The connection electrode CNE may be connected to the first hold capacitor Cpr1, the second transistor TR2, the third transistor TR3, the second hold capacitor Cpr2, and the fifth transistor TR5.

In accordance with the embodiments of the present disclosure, the first pixel PXL1 and the second pixel PXL2′ can be integrally compensated by the connection electrode CNE.

In accordance with the embodiments of the present disclosure, the storage capacity of the first and second hold capacitors Cpr1 and Cpr2 can be increased.

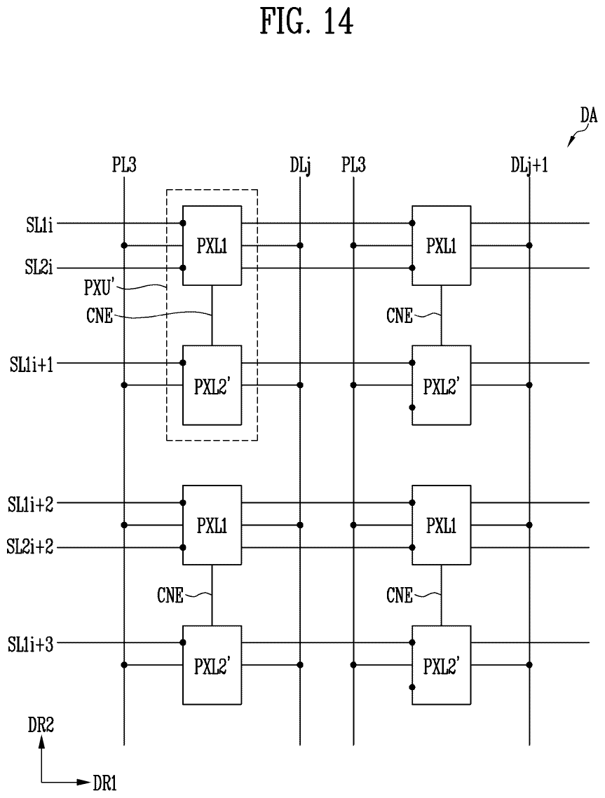

FIG. 14 is a diagram briefly illustrating at least a portion of a display area DA in accordance with another embodiment of the present disclosure.

As compared with the embodiment illustrated in FIG. 5, the unit pixel PXU′ may be connected to three scan lines. However, embodiments of the present disclosure are not limited. For example, the unit pixel PXU′ may be connected to at least three first scan lines while being connected to one second scan line. In one or more embodiments, a quantity of first scan lines disposed in the display area DA may be at least two times greater than a quantity of second scan lines disposed in the display area DA. Hereinafter, an embodiment in which the unit pixel PXU′ is connected two first scan lines and one second scan line will be described as an example. However, embodiments of the present disclosure are not limited thereto.

A unit pixel PXU′ located at a left upper end may be connected to an ith first scan line SL1i, an ith second scan line SL2i, and a (i+1)th first scan line SL1i+1.

As compared with the embodiment illustrated in FIG. 5, the (i+1)th second scan line SL2i+1 may be omitted in the display area DA. Accordingly, as the (i+1)th second scan line SL2i+1 is omitted, the degree of integration of pixels can be improved. Thus, for example, the PPI can be further increased.

In some aspects, the configuration of the scan driving circuit 130 (see FIG. 1) for supplying a scan signal to the (i+1)th second scan line SL2i+1 may be omitted. Accordingly, the configuration of the scan driving circuit 130 can be further simplified, and the area of an area (e.g., the non-display area NDA (see FIG. 1)) in which the scan driving circuit 130 is disposed can be decreased. Thus, for example, the area of the display area DA can become relatively wider.

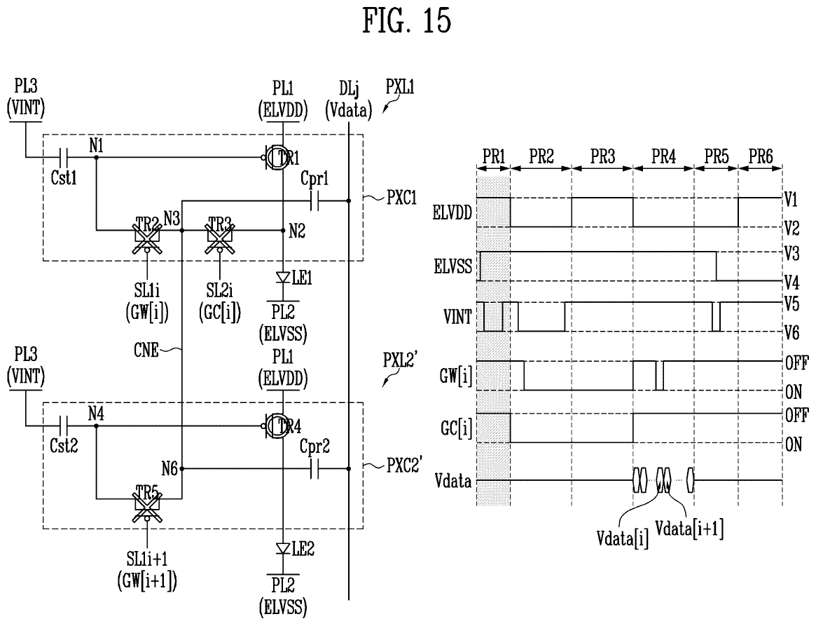

FIGS. 15 to 20 are diagrams illustrating the method 600 (see FIG. 6) in the unit pixel PXU′ illustrated in FIG. 13.

Referring to FIG. 15, the first pixel PXL1 and the second pixel PXL2′ in the first period PR1 are illustrated.

In the first period PR1, the second transistor TR2 and the fifth transistor TR5 may be off. The first scan signals GW[i] and GW[i+1] may have the off-level OFF.

In the first period PR1, the third transistor TR3 may be off. The second scan signal GC[i] may have the off level OFF. The first power voltage ELVDD may have the first voltage V1. The second power voltage ELVSS may have the third voltage V3. The third power voltage VINT may be decreased from the fifth voltage V5 to the sixth voltage V6 and then again increased to the fifth voltage V5. Accordingly, a voltage of each of the first node N1 and the fourth node N4 may also be decreased and then again increased. Accordingly, an on-bias voltage having a turn-on level may be applied to the first and fourth transistors TR1 and TR4, and no driving current may flow through the first and second light emitting elements LE1 and LE2 as the second power voltage ELVSS has the third voltage V3 which has a high level.

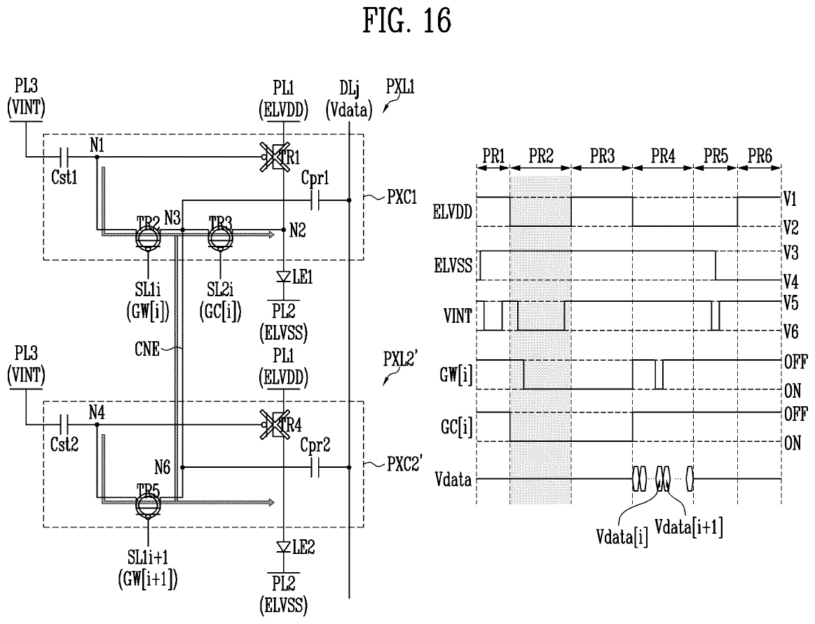

Referring to FIG. 16, the first pixel PXL1 and the second pixel PXL2′ in the second period PR2 are illustrated.

In the second period PR2, the second transistor TR2 and the fifth transistor TR5 may be on. The first scan signals GW[i] and GW[i+1] may have the on-level ON.

In the second period PR2, the third transistor TR3 may be on. The second scan signal GC[i] may have the on-level ON.

The first node N1, the second node N2, and the third node N3 may be electrically connected to each other. In an example, in response to a voltage level (i.e., third power voltage VINT) of the third power line PL3 being changed from the fifth voltage V5 to the sixth voltage V6, a voltage of each of the first to third nodes N1 to N3 may also be changed and initialized.

The fourth node N4 and the sixth node N6 may be electrically connected to each other. In an example, in response to a voltage level (i.e., third power voltage VINT) of the third power line PL3 being changed from the fifth voltage V5 to the sixth voltage V6, a voltage of each of fourth node N4 and the sixth node N6 may also be changed and initialized.

The second node N2, the third node N3, and the sixth node N6 may be electrically connected to each other by the connection electrode CNE.

The first power voltage ELVDD may have the second voltage V2. The second power voltage ELVSS may have the third voltage V3. Accordingly, no driving current may flow toward the first light emitting element LE1 through the first transistor TR1. No driving current may flow toward the second light emitting element LE2 through the fourth transistor TR4.

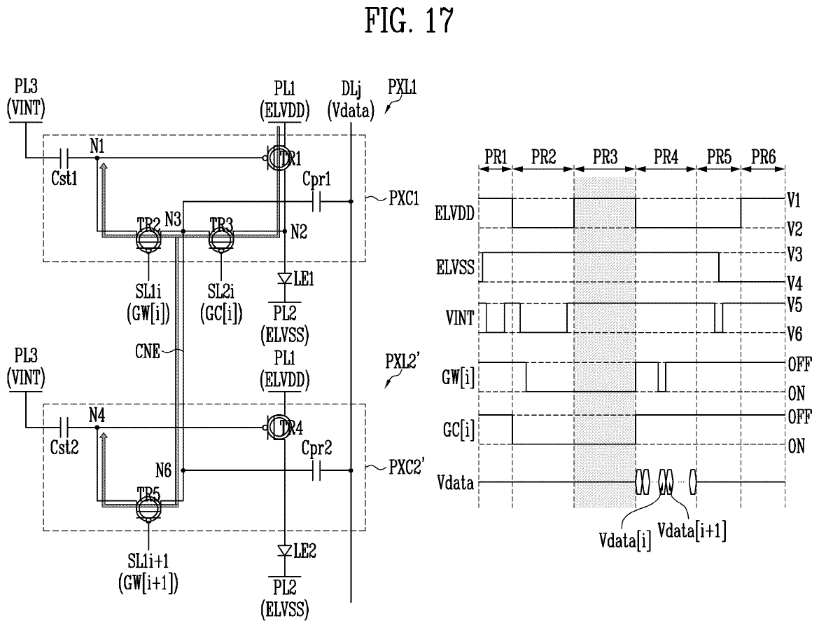

Referring to FIG. 17, the first pixel PXL1 and the second pixel PXL2′ in the third period PR3 are illustrated.

In the third period PR3, the second transistor TR2 and the fifth transistor TR5 may be on. The first scan signals GW[i] and GW[i+1] may have the on-level ON.

In the third period PR3, the third transistor TR3 may be on. The second scan signal GC[i] may have the on-level ON.

The first power voltage ELVDD may have the first voltage V1. Accordingly, the first transistor TR1 may be diode-connected. Thus, for example, a characteristic value change of the first transistor TR1 (e.g., a change in threshold voltage of the first transistor T1) can be compensated. The first power voltage ELVDD having the first voltage V1 may be applied to the fourth transistor TR4, and a voltage obtained by reflecting the characteristic value change of the first transistor TR1 (e.g., the change in threshold voltage of the first transistor T1) may be applied to the gate electrode of the fourth transistor TR4. In some embodiments, the first transistor TR1 and the fourth transistor TR4 may be located adjacent to each other, and a degree to which the first transistor TR1 is degraded while an image is displayed and a degree to which the fourth transistor TR4 is degraded while the image is displayed may be substantially similar to each other. Accordingly, a voltage obtained by compensating for the characteristic value change of the first transistor TR1 may be used to compensate for a characteristic value change of the fourth transistor TR4. Accordingly, the voltage obtained by compensating for the characteristic value change of the first transistor TR1 may be applied to the fourth node N4, and the corresponding voltage may be used to compensate for the characteristic value change of the fourth transistor TR4.

Accordingly, the characteristic value changes of the first transistor TR1 and the fourth transistor TR4 can be integrally compensated.

The second power voltage ELVSS may have the third voltage V3. Accordingly, no driving current may flow toward the first light emitting element LE1 from the first transistor TR1. No driving current may flow toward the second light emitting element LE2 from the fourth transistor TR4.

The third power voltage VINT may have the fifth voltage V5. The substantially same potential difference may be formed at both ends of the first storage capacitor Cst1 and the second storage capacitor Cst2.

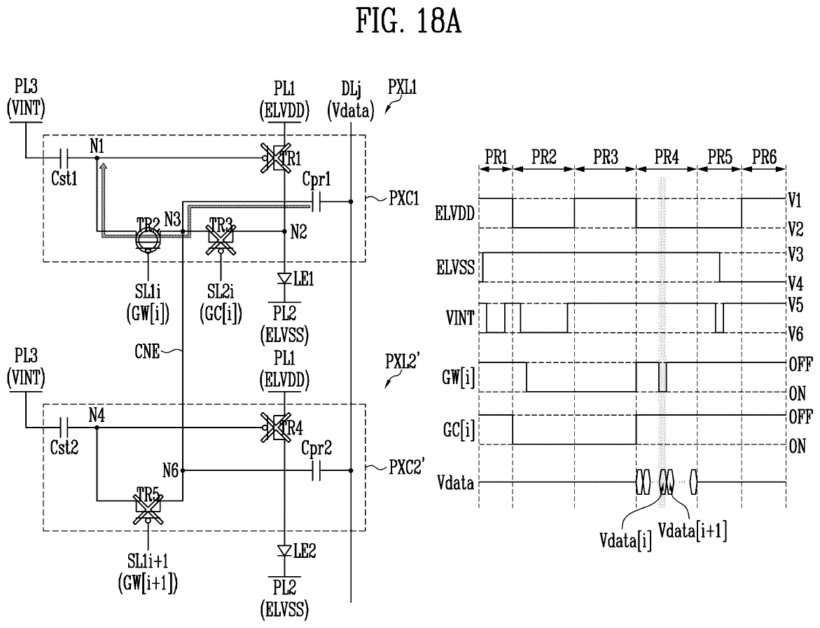

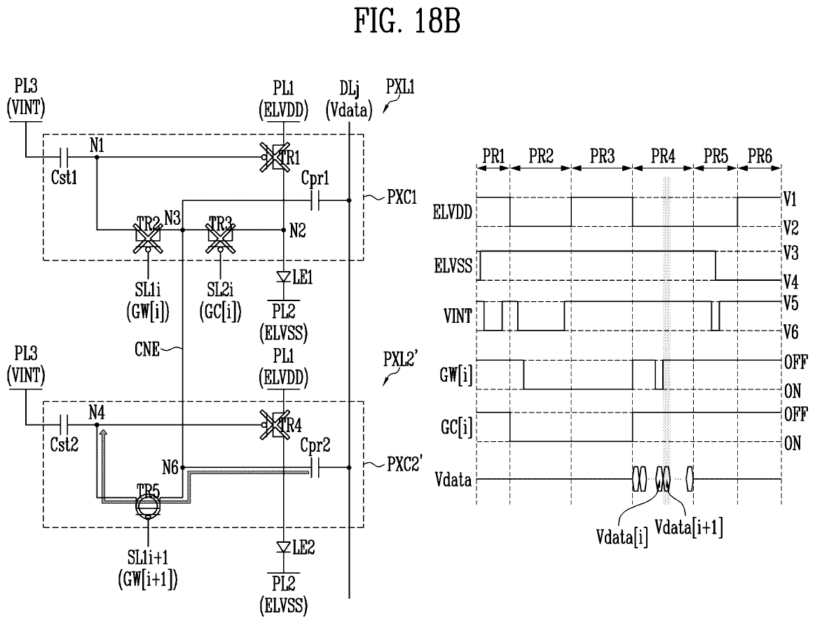

Referring to FIG. 18A, the first pixel PXL1 and the second pixel PXL2′ in at least a partial period of the fourth period PR4 are illustrated.

Referring to FIG. 18A, in the at least a partial period of the fourth period PR4, a data voltage Vdata[i] input to the first pixel PXL1 may be applied to the jth data line DLj.

The second transistor TR2 may be turned on based on a voltage level of the first scan signal GW[i]. The first scan signal GW[i] having a turn-on level may be applied to the ith first scan line SL1i. By a coupling effect of the first hold capacitor Cpr1, the voltage of the third node N3 may be changed to have a magnitude corresponding to the data voltage Vdata[i]. The first node N1 and the third node N3 may be electrically connected to each other, and a voltage corresponding to the data voltage Vdata[i] may be applied to the first node N1.

The first transistor TR1 and the third transistor TR3 may be off. The fourth transistor TR4 and the fifth transistor TR5 may be off.

Referring to FIG. 18B, the first pixel PXL1 and the second pixel PXL2′ in the other period of the fourth period PR4 are illustrated.

Referring to FIG. 18B, in the other period of the fourth period PR4, a data voltage Vdata[i+1] input to the second pixel PXL2′ may be applied to the jth data line DLj.

The fifth transistor TR5 may be turned on based on a voltage level of the first scan signal GW[i+1]. The first scan signal GW[i+1] may be applied to the (i+1)th first scan line SL1i+1. By a coupling effect of the second hold capacitor Cpr2, the voltage of the sixth node N6 may be changed to have a magnitude corresponding to the data voltage Vdata[i+1]. The fourth node N4 may be electrically connected to the sixth node N6, and a voltage corresponding to the data voltage Vdata[i+1] may be applied to the fourth node N4.

The fourth transistor TR4 may be off. The first to third transistors TR1 o TR3 may be off.

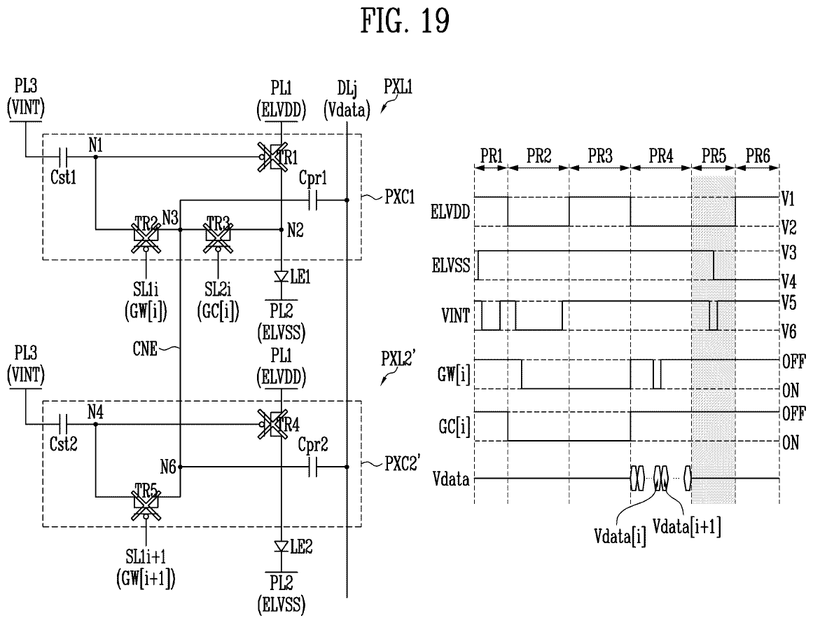

Referring to FIG. 19, the first pixel PXL1 and the second pixel PXL2′ in the fifth period PR5 are illustrated.

The first power voltage ELVDD may have the second voltage V2. The second power voltage ELVSS may be decreased from the third voltage V3 to the fourth voltage V4.

The third power voltage VINT may be decreased from the fifth voltage V5 to the sixth volage V6 and then again increased to the fifth voltage V5 before/after a time point at which the second power voltage ELVSS is decreased from the third voltage V3 to the fourth voltage V4.

The first to fifth transistors TR1 to TR5 may all be off.

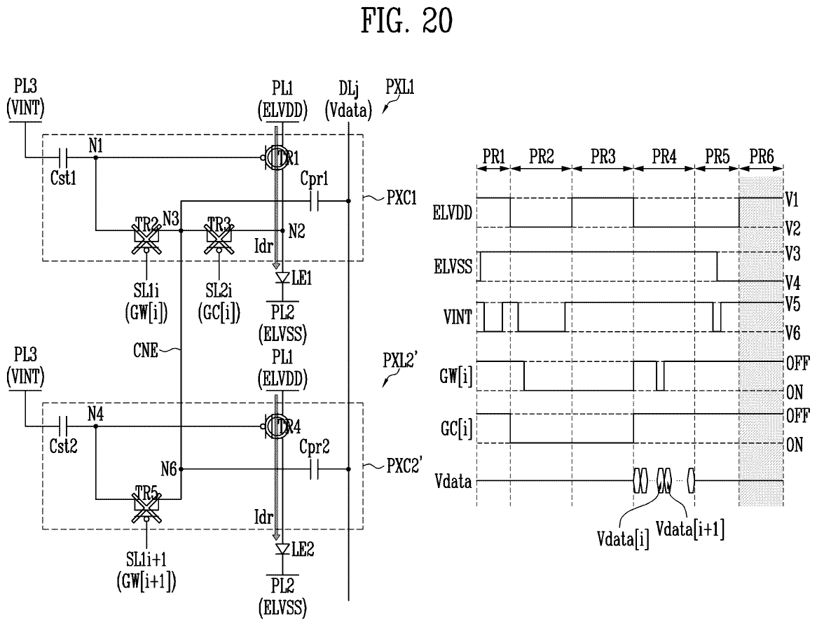

Referring to FIG. 20, the first pixel PXL1 and the second pixel PXL2′ in the sixth period PR6 are illustrated.

The first power voltage ELVDD may have the first voltage V1. The second power voltage ELVSS may have the fourth voltage V4.

Accordingly, the first transistor TR1 may provide a driving current Idr having a magnitude corresponding to the voltage of the first node N1. The fourth transistor TR4 may provide the driving current Idr having a magnitude corresponding to the voltage of the fourth node N4.

The second transistor TR2, the third transistor TR3, and the fifth transistor TR5 may be off.

The first pixel PXL1 and the second pixel PXL2′ may emit light simultaneously (or during the same period).

In accordance with the embodiments of the present disclosure, the characteristic value changes of the first transistor TR1 and the fourth transistor TR4 can be integrally compensated.

In some aspects, an effect can be exhibited like that electrodes of the first hold capacitor Cpr1 and the second hold capacitor Cpr2 are electrically connected to each other.

Accordingly, display quality can be improved. Further, the degree of integration of pixels can be improved, thereby increasing the PPI.

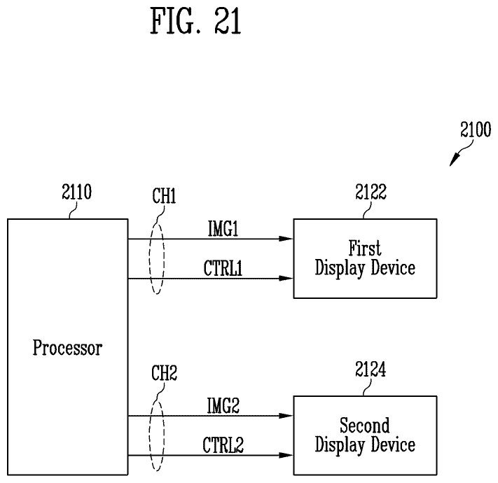

FIG. 21 is a diagram illustrating an embodiment of a display system 2100 in accordance with embodiments of the present

Referring to FIG. 21, the display system 2100 may include a processor 2110 and one or more display devices 2122 and 2124. The display system 2100 may be provided as the electronic device DS which is illustrated in FIG. 1.

The processor 2110 may perform various tasks and various calculations. In embodiments, the processor 2110 may include an Application Processor (AP), a Graphics Processing Unit (GPU), a microprocessor, a Central Processing Unit (CPU), and the like. The processor 2110 may be connected to other components of the display system 2100 through a bus system to control the components of the display system 2100.

In FIG. 21, it is illustrated that the display system 2100 includes first and second display devices 2122 and 2124. The processor 2110 may be connected to the first display device 2122 through a first channel CH1, and be connected to the second display device 2124 through a second channel CH2.

Through the first channel CH1, the processor 2110 may transmit first image data IMG1 and a first control signal CTRL1 to the first display device 2122. The first display device 2122 may display an image, based on the first image data IMG1 and the first control signal CTRL1. The first display device 2122 may be configured identically to the display device 100 described with reference to FIG. 1. The first image data IMG1 and the first control signal CTRL1 may be respectively provided as the first image data DATA1 and the control signal CTRL, which are illustrated in FIG. 1.

Through the second channel CH2, the processor 2110 may transmit second image data IMG2 and a second control signal CTRL2 to the second display device 2124. The second display device 2124 may display an image, based on the second image data IMG2 and the second control signal CTRL2. The second display device 2124 may be configured identically to the display device 100 described with reference to FIG. 1. The second image data IMG2 and the second control signal CTRL2 may be respectively provided as the first image data DATA1 and the control signal CTRL, which are illustrated in FIG. 1.

The processor 2110 may be configured identically to the host HST described with reference to FIG. 1.

The display system 2100 may include a computing system for providing an image display function, such as, for example, a portable computer, a mobile phone, a smartphone, a tablet personal computer (PC), a smart watch, a watch phone, a portable multimedia player (PMP), a navigation system, or an ultra-mobile computer (UMPC). In some aspects, the display system 2100 may include at least one of a head mounted display (HMD) device, a virtual reality (VR) device, a mixed reality (MR) device, and an augmented reality (AR) device.

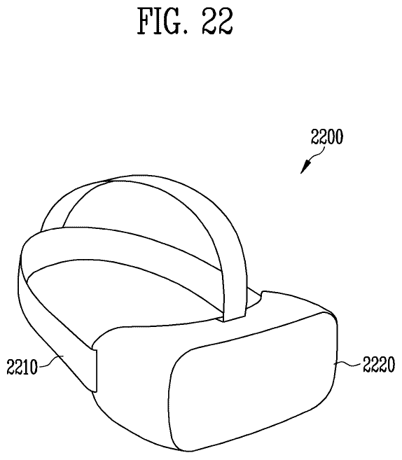

FIG. 22 is a view illustrating an application example of the display system 2100 illustrated in FIG. 21.

Referring to FIG. 22, the display system 2100 illustrated in FIG. 21 may be applied to a head mounted display device 2200. The head mounted display device 2200 may be a wearable electronic device which can be worn on a head of a user.

The head mounted display device 2200 may include a head mounting band 2210 and a display device accommodating case 2220. The head mounting band 2210 may be connected to the display device accommodating case 2220. The head mounting band 2210 may include a horizontal band and/or a vertical band, used to fix the head mounted display device 2200 to the head of the user. The horizontal band may be configured to surround a side portion of the head of the user, and the vertical band may be configured to surround an upper portion of the head of the user. However, embodiments are not limited thereto. For example, the head mounting band 2210 may be implemented in the form of a glasses frame, a helmet or the like.

The display device accommodating case 2220 may accommodate the first and second display devices 2122 and 2124 illustrated in FIG. 21. The display device accommodating case 2220 may further accommodate the processor 2110 illustrated in FIG. 21.

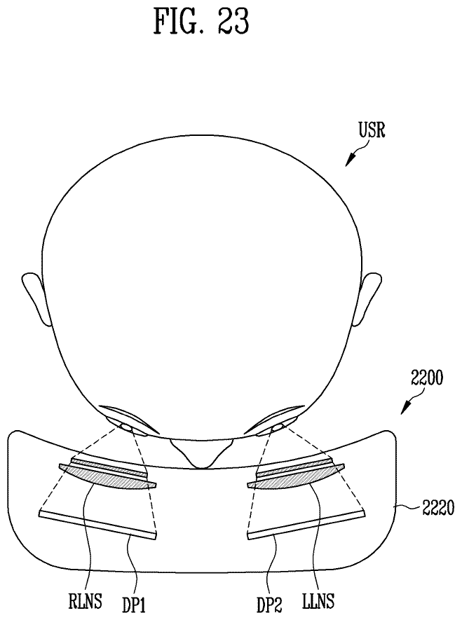

FIG. 23 is a view illustrating the head mounted display device 2200 worn by a user USR.

Referring to FIG. 23, a first display panel DP1 of the first display device 2122 (see FIG. 21) and a second display panel DP2 of the second display device 2124 (see FIG. 21) may be disposed in the head mounted display device 2200. The head mounted display device 2200 may further include one or more lenses. For example, the head mounted display device 2200 may further include a left-eye lens LLNS and a right-eye lens RLNS.

In the display device accommodating case 2220, the right-eye lens RLNS may be disposed between the first display panel DP1 and a right eye of the user USR. In the display device accommodating case 2220, the left-eye lens LLNS may be disposed between the second display panel DP2 and a left eye of the user.

An image output from the first display panel DP1 may be viewed by the right eye of the user USR through the right-eye lens RLNS. The right-eye lens RLNS may refract light emitted from the first display panel DP1 to face the right eye of the user USR. The right-eye lens RLNS may perform an optical function for adjusting a viewing distance between the first display panel DP1 and the right eye of the user USR.

An image output from the second display panel DP2 may be viewed by the left eye of the user USR through the left-eye lens LLNS. The left-eye lens LLNS may refract light emitted from the second display panel DP2 to face the left eye of the user USR. The left-eye lens LLNS may perform an optical function for adjusting a viewing distance between the second display panel DP2 and the left eye of the user USR.

In embodiments, each of the right-eye lens RLNS and the left-eye lens LLNS may include an optical lens having a pancake-shaped section. In embodiments, each of the right-eye lens RLNS and the left-eye lens LLNS may include a multi-channel lens including sub-areas having different optical characteristics. In one or more embodiments, each of the first and second display panels DP1 and DP2 may output images respectively corresponding to the sub-areas of the multi-channel lens, and the output images may be viewed by the user USR while respectively passing through corresponding sub-areas.

In the display panel, the display device including the display panel, and the electronic device including the display panel in accordance with the present disclosure, the degree of integration of pixels can be increased.

Example embodiments have been disclosed herein, and although specific terms are employed, the terms are used and are to be interpreted in a generic and descriptive sense and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display panel comprising:
a display area in which a first pixel and a second pixel connected to the first pixel through a connection electrode are disposed; and
a non-display area at a periphery of the display area,
wherein:
the first pixel comprises:
a first transistor comprising a gate electrode connected to a first node, the first transistor being connected between a first power line and a second node;
a second transistor connected between the first node and a third node;
a third transistor connected between the second node and the third node; and
a first hold capacitor comprising an electrode connected to the connection electrode through the third node and another electrode connected to a data line, and the second pixel comprises:
a fourth transistor comprising a gate electrode connected to a fourth node, the fourth transistor being connected to the first power line;
a fifth transistor connected between the fourth node and a sixth node; and
a second hold capacitor comprising an electrode connected to the connection electrode through the sixth node and another electrode connected to the data line.

2. The display panel of claim 1, wherein:
the first pixel further comprises a first storage capacitor comprising an electrode connected to the first node and another electrode connected to a third power line, and
the second pixel further comprises a second storage capacitor comprising an electrode connected to the fourth node and another electrode connected to the third power line.

3. The display panel of claim 1, wherein each of the first to fifth transistors comprises a P-type semiconductor.

4. The display panel of claim 1, wherein:
a second power line to which a second power voltage is applied is further disposed in the display area,
the first pixel further comprises a first light emitting element disposed between the first transistor and the second power line, and
the second pixel further comprises a second light emitting element disposed between the fourth transistor and the second power line.

5. The display panel of claim 4, wherein the first light emitting element and the second light emitting element are configured to simultaneously emit light.

6. The display panel of claim 1, wherein:
the second transistor comprises a gate electrode connected to an ith first scan line, wherein i is an integer of 1 or more,
the third transistor comprises a gate electrode connected to ith second scan line, and
the fifth transistor comprises a gate electrode connected to an (i+1)th first scan line.

7. The display panel of claim 6, wherein a quantity of first scan lines disposed in the display area is equal to a quantity of second scan lines disposed in the display area.

8. The display panel of claim 6, wherein a quantity of first scan lines disposed in the display area is at least two times greater than a quantity of second scan lines disposed in the display area.

9. The display panel of claim 6, wherein:
each of the ith first scan line, the ith second scan line, and an (i+1)th first scan line extends in a first direction,
the data line extends in a second direction different from the first direction, and
the connection electrode extends in the second direction.

10. The display panel of claim 1, wherein:
the fourth transistor is connected between the first power line and a fifth node, and
the second pixel further comprises a sixth transistor connected between the fifth node and the sixth node, and
wherein:
the second transistor comprises a gate electrode connected to an ith first scan line, wherein i is an integer of 1 or more,
the third transistor comprises a gate electrode connected to an ith second scan line,
the fifth transistor comprises a gate electrode connected to an (i+1)th first scan line, and
the sixth transistor comprises a gate electrode connected to an (i+1)th second scan line.

11. The display panel of claim 10, wherein the display panel is configured to integrally initialize respective voltages of the second node and the fifth node.

12. The display panel of claim 1, wherein the display panel is configured to integrally compensate respective characteristic value changes of the first transistor and the fourth transistor.

13. A display device, comprising:
a display panel in which a unit pixel, a data line, and a first power line are disposed, wherein the unit pixel comprises a first pixel, a second pixel, and a connection electrode connected to the first pixel and the second pixel; and
a data driving circuit configured to supply a data voltage to the data line,
wherein the first pixel comprises:
a first transistor comprising a gate electrode connected to a first node, the first transistor being connected between the first power line and a second node;
a second transistor connected between the first node and a third node;
a third transistor connected between the second node and the third node; and
a first hold capacitor comprising an electrode connected to the connection electrode through the third node and another electrode connected to the data line, and wherein the second pixel comprises:
a fourth transistor comprising a gate electrode connected to a fourth node, the fourth transistor being connected to the first power line;
a fifth transistor connected between the fourth node and a sixth node; and
a second hold capacitor comprising an electrode connected to the connection electrode through the sixth node and another electrode connected to the data line.

14. The display device of claim 13, further comprising a power supply circuit configured to supply a first power voltage to the first power line such that the first power voltage alternately has a first voltage of a high level and a second voltage of a low level.

15. The display device of claim 14, wherein the power supply circuit is configured to:
supply the first power voltage such that the first power voltage has the first voltage in a first period, wherein the first period is an on-bias period;
supply the first power voltage such that the first power voltage has the second voltage in a second period, wherein the second period is an initialization period;
supply the first power voltage such that the first power voltage has the first voltage in a third period, wherein the third period is a compensation period;
supply the first power voltage such that the first power voltage has the second voltage in a fourth period and a fifth period, wherein the fourth period is a data writing period and the fifth period is a margin period; and
supply the first power voltage such that the first power voltage has the first voltage in a sixth period, wherein the sixth period is an emission period.

16. The display device of claim 15, wherein:
a third power line is further disposed in the display panel,
the first pixel further comprises a first storage capacitor comprising an electrode connected to the first node and another electrode connected to the third power line,
the second pixel further comprises a second storage capacitor comprising an electrode connected to the fourth node and another electrode connected to the third power line, and
the power supply circuit is configured to supply, to the third power line, a third power voltage such that the third power voltage alternately has a fifth voltage of a high level and a sixth voltage of a low level.

17. The display device of claim 16, wherein the power supply circuit is configured to:
supply the third power voltage such that the third power voltage has the sixth voltage in the first period and the second period;
supply the third power voltage such that the third power voltage has the fifth voltage in the third period and the fourth period;
supply the third power voltage such that the third power voltage has the sixth voltage in the fifth period; and
supply the third power voltage such that the third power voltage has the fifth voltage in the sixth period.

18. The display device of claim 17, wherein:
a second power line to which a second power voltage is applied is further disposed in the display panel,
the first pixel further comprises a first light emitting element disposed between the first transistor and the second power line,
the second pixel further comprises a second light emitting element disposed between the fourth transistor and the second power line, and
the power supply circuit is configured to:
supply the second power voltage such that the second power voltage has a third voltage of a high level in the first to fourth periods; and
supply the second power voltage such that the second power voltage has a fourth voltage of a low level in the fifth period and the sixth period.

19. The display device of claim 18, further comprising a scan driving circuit configured to:
supply a first scan signal to each of a plurality of first scan lines disposed in the display panel, and
supply a second scan signal to each of a plurality of second scan lines disposed in the display panel,
wherein:
the second transistor comprises a gate electrode connected to an ith first scan line among the plurality of first scan lines, wherein i is an integer of 1 or more,
the third transistor comprises a gate electrode connected to an ith second scan line among the plurality of second scan lines,
the fifth transistor comprises a gate electrode connected to an (i+1)th first scan line among the plurality of first scan lines,
a sixth transistor comprised in the second pixel comprises a gate electrode connected to an (i+1)th second scan line among the plurality of second scan lines, and
the scan driving circuit is configured to:
supply the first scan signal such that the first scan signal has an off-level to the ith first scan line in the first period, the fifth period, and the sixth period;
supply the first scan signal such that the first scan signal has an on-level to the ith first scan line in the second period, the third period, and the fourth period;
supply the second scan signal such that the second scan signal has an off-level to the ith second scan line in the first period, the fourth period, the fifth period, and the sixth period; and
supply the second scan signal such that the second scan signal has an on-level to the ith second scan line in the second period and the third period.

20. An electronic device, comprising:
a processor configured to output first image data; and
a display device configured to display an image corresponding to the first image data,
wherein the display device comprises:
a display panel in which a unit pixel, a data line, and a first power line are disposed, wherein the unit pixel comprises a first pixel, a second pixel, and a connection electrode connected to the first pixel and the second pixel; and
a data driving circuit configured to supply a data voltage corresponding to the first image data to the data line,
wherein:
the first pixel comprises:
a first transistor comprising a gate electrode connected to a first node, the first transistor being connected between the first power line and a second node;
a second transistor connected between the first node and a third node;
a third transistor connected between the second node and the third node; and
a first hold capacitor comprising an electrode connected to the connection electrode through the third node and another electrode connected to the data line, and the second pixel comprises:
a fourth transistor comprising a gate electrode connected to a fourth node, the fourth transistor being connected to the first power line;
a fifth transistor connected between the fourth node and a sixth node; and
a second hold capacitor comprising an electrode connected to the connection electrode through the sixth node and another electrode connected to the data line.
